(19) United States
(12) Patent Application Publication
(10) Pub. No.: US 2024/0332171 A1
(43) Pub. Date: Oct. 3, 2024

(54) INSULATION CHIP AND SIGNAL TRANSMISSION DEVICE

(71) Applicant: ROHM CO., LTD., Kyoto (JP)

(72) Inventor: Keiji WADA, Kyoto (JP)

(21) Appl. No.: 18/614,921

(22) Filed: Mar. 25, 2024

(30) Foreign Application Priority Data
Mar. 27, 2023 (JP) 2023-050129

(51) Int. Cl. H01L 23/522; H01L 23/00; H01L 23/495; H01L 25/065

(52) U.S. Cl. CPC H01L 23/5227; H01L 23/4951; H01L 23/49575; H01L 24/08; H01L 24/48; H01L 25/0657; H01L 2224/08145; H01L 2224/08245; H01L 2224/48145; H01L 2224/48247; H01L 2225/0651; H01L 2225/06541; H01L 2924/0665; H01L 2924/182

(57) ABSTRACT

An insulation chip includes a first unit, and a second unit bonded to the first unit and smaller in size than the first unit in a plan view. The first unit includes a first element insulating layer, a first insulating element buried in the first element insulating layer, and a first electrode pad provided on the first element insulating layer. The second unit includes a second element insulating layer, and a second insulating element buried in the second element insulating layer. In a unit bonding state in which the second unit is bonded to the first unit, the first and second insulating elements are arranged to face each other in a thickness direction of the first element insulating layer, and the first electrode pad is provided at a different position from the second unit in a plan view.

### CROSS-REFERENCE TO RELATED APPLICATION

This application is based upon and claims the benefit of priority from Japanese Patent Application No. 2023-050129, filed on Mar. 27, 2023, the entire contents of which are incorporated herein by reference.

### TECHNICAL FIELD

The present disclosure relates to an insulation chip and a signal transmission device.

### BACKGROUND

As an example of a signal transmission device, an insulated gate driver that applies a gate voltage to a gate of a switching element such as a transistor is known. As an example of an insulation chip used in such a gate driver, in an element insulating layer, a structure that includes a first coil and a second coil arranged to face each other in a thickness direction of the element insulating layer is known.

### BRIEF DESCRIPTION OF DRAWINGS

The accompanying drawings, which are incorporated in and constitute a part of the specification, illustrate embodiments of the present disclosure.

FIG. 1 is a circuit diagram schematically showing a circuit configuration of a signal transmission device according to a first embodiment.

FIG. 2 is a schematic plan view schematically showing a configuration of the signal transmission device of FIG. 1.

FIG. 3 is a schematic cross-sectional view schematically showing the configuration of the signal transmission device of FIG. 2.

FIG. 4 is a schematic plan view schematically showing a first unit of an insulation chip in the signal transmission device.

FIG. 5 is a schematic cross-sectional view of the first unit taken along line F5-F5 in FIG. 4.

FIG. 6 is a schematic cross-sectional view of the first unit taken along line F6-F6 in FIG. 4.

FIG. 7 is a schematic plan view schematically showing a second unit of the insulation chip in the signal transmission device.

FIG. 8 is a schematic cross-sectional view of the second unit taken along line F8-F8 in FIG. 7.

FIG. 9 is a schematic cross-sectional view of the second unit taken along line F9-F9 in FIG. 7.

FIG. 10 is a schematic cross-sectional view of the first unit and the second unit of the insulation chip in a separated state.

FIG. 11 is a schematic plan view schematically showing the insulation chip.

FIG. 12 is a schematic cross-sectional view of the insulation chip taken along line F12-F12 in FIG. 11.

FIG. 13 is a schematic cross-sectional view of the insulation chip taken along line F13-F13 in FIG. 11.

FIG. 14 is a schematic cross-sectional view of the insulation chip taken along line F14-F14 in FIG. 11.

FIG. 15 is a schematic perspective view showing a process of manufacturing the insulation chip.

FIG. 16 is a circuit diagram schematically showing a circuit configuration of a signal transmission device according to a second embodiment.

FIG. 17 is a schematic plan view schematically showing an insulation chip in the signal transmission device of FIG. 16.

FIG. 18 is a schematic cross-sectional view of the insulation chip taken along line F18-F18 in FIG. 17.

FIG. 19 is a schematic cross-sectional view showing an insulation chip according to a modification.

FIG. 20 is a schematic cross-sectional view showing an insulation chip according to a modification.

FIG. 21 is a schematic cross-sectional view showing an insulation chip according to a modification.

FIG. 22 is a schematic cross-sectional view schematically showing a configuration of a signal transmission device according to a modification.

FIG. 23 is a schematic cross-sectional view schematically showing a configuration of a signal transmission device according to a modification.

FIG. 24 is a schematic cross-sectional view schematically showing a configuration of a signal transmission device according to a modification.

FIG. 25 is a schematic cross-sectional view schematically showing a configuration of a signal transmission device according to a modification.

### DETAILED DESCRIPTION

Hereinafter, some embodiments of an insulation chip and a signal transmission device according to the present disclosure will be described with reference to the accompanying drawings. It should be noted that, for simplicity and clarity of explanation, components shown in the drawings are not necessarily drawn to scale. Further, in order to facilitate understanding, hatching lines may be omitted in cross-sectional views. The accompanying drawings merely illustrate embodiments of the present disclosure and should not be considered as limiting the present disclosure.

The following detailed description includes devices, systems, and methods embodying exemplary embodiments of the present disclosure. This detailed description is for illustrative purposes only and is not intended to limit the embodiments of the present disclosure or the applications and uses of such embodiments.

### First Embodiment

### [Configuration of Signal Transmission Device]

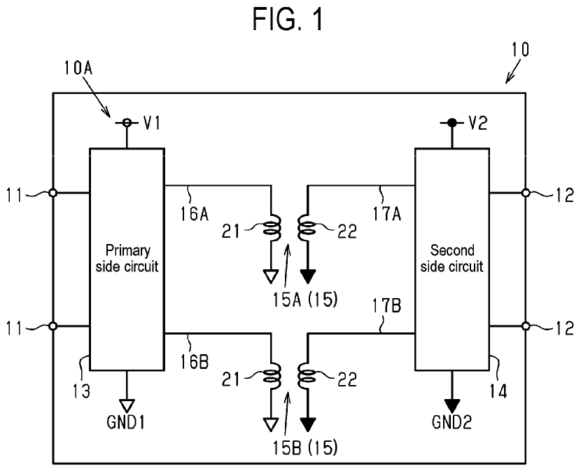

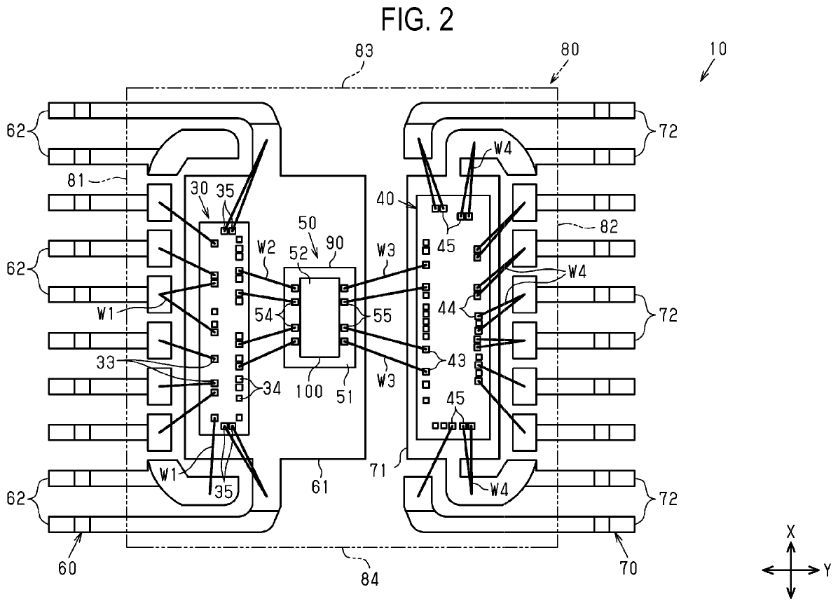

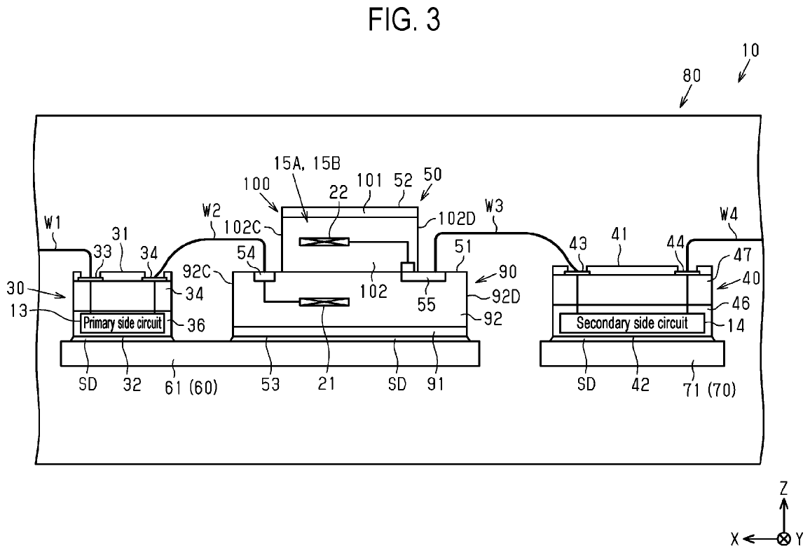

A schematic configuration of a signal transmission device 10 according to a first embodiment will be described with reference to FIGS. 1 to 3. FIG. 1 shows a simplified example of a circuit configuration of the signal transmission device 10 of the first embodiment. FIG. 2 shows a schematic planar structure of an interior of the signal transmission device 10 of the first embodiment. FIG. 3 shows a simplified internal structure of a portion of the signal transmission device 10 of FIG. 2. Note that hatching lines are omitted in FIG. 3 to facilitate understanding of the drawings.

As shown in FIG. 1, the signal transmission device 10 is configured to transmit a pulse signal while electrically insulating a primary-side terminal 11 and a secondary-side terminal 12. The signal transmission device 10 is, for example, a digital isolator. An example of the digital isolator is a DC/DC converter. The signal transmission device 10 includes a signal transmission circuit 10A including a primary-side circuit 13 electrically connected to the primary-side terminal 11, a secondary-side circuit 14 electrically connected to the secondary-side terminal 12, and a transformer 15 that electrically insulates the primary-side circuit 13 from the secondary-side circuit 14. Here, in the present disclosure, the primary-side circuit 13 corresponds to a “first circuit,” and the secondary-side circuit 14 corresponds to a “second circuit.”

The primary-side circuit 13 is configured to operate when a first voltage V1 is applied thereto. The primary-side circuit 13 is electrically connected to, for example, an external control device (not shown). The secondary-side circuit 14 is configured to operate when a second voltage V2 different from the first voltage V1 is applied thereto. The first voltage V1 and the second voltage V2 are DC voltages. The secondary-side circuit 14 is electrically connected to, for example, a drive circuit (not shown) to be controlled by a control device. An example of the drive circuit is a switching circuit including a switching element. Examples of the switching element may include SiMOSFET, SiCMOSFET, IGBT, and the like. The secondary-side circuit 14 is electrically connected to the gate of the switching element. Further, the secondary-side circuit 14 supplies a gate drive signal to the gate of the switching element.

In the signal transmission circuit 10A, when a control signal from the control device is input to the primary-side circuit 13 via the primary-side terminal 11, a signal is transmitted from the primary-side circuit 13 to the secondary-side circuit 14 via the transformer 15. Then, the signal transmitted to the secondary-side circuit 14 is output from the secondary-side circuit 14 to the drive circuit via the secondary-side terminal 12.

The signal transmitted from the primary-side circuit 13 to the secondary-side circuit 14, that is, the signal output from the primary-side circuit 13, is, for example, a signal for driving the switching element. Examples of this signal may include a set signal (SET) and a reset signal (RESET). The set signal is a signal that transmits the rise of the control signal from the control device, and the reset signal is a signal that transmits the fall of the control signal from the control device. It can be said that the set signal and the reset signal are signals for generating the gate drive signal of the switching element.

More specifically, the primary-side circuit 13 generates the set signal and the reset signal based on the control signal input from the control device. In one example, the primary-side circuit 13 generates the set signal in response to a rising edge of the control signal and generates the reset signal in response to a falling edge of the control signal. Then, the primary-side circuit 13 transmits the generated set signal and reset signal to the secondary-side circuit 14.

The secondary-side circuit 14 generates the gate drive signal for driving the switching element based on the set signal and the reset signal received from the primary-side circuit 13. Then, the secondary-side circuit 14 supplies the gate drive signal to the gate of the switching element. In other words, it can be said that the secondary-side circuit 14 generates the gate drive signal to be supplied to the gate of the switching element based on a first signal output from the primary-side circuit 13. More specifically, the secondary-side circuit 14 generates the gate drive signal for turning on the switching element based on the set signal, and then supplies the gate drive signal to the gate of the switching element. On the other hand, the secondary-side circuit 14 generates the gate drive signal for turning off the switching element based on the reset signal, and then supplies the gate drive signal to the gate of the switching element. In this way, the signal transmission device 10 controls the turn-on/off of the switching element.

The secondary-side circuit 14 includes, for example, an RS type flip-flop circuit to which the set signal and the reset signal are input, and a driver part that generates the gate drive signal based on an output signal of the RS type flip-flop circuit. However, a specific circuit configuration of the secondary-side circuit 14 may be changed arbitrarily.

As described above, the primary-side circuit 13 and the secondary-side circuit 14 are electrically insulated from each other by the transformer 15. More specifically, while the transformer 15 restricts the transmission of a DC voltage between the primary-side circuit 13 and the secondary-side circuit 14, it is possible to transmit various signals such as the set signal and the reset signal between the primary-side circuit 13 and the secondary-side circuit 14.

In other words, the state in which the primary-side circuit 13 and the secondary-side circuit 14 are insulated from each other means a state in which the transmission of a DC voltage is cut off between the primary-side circuit 13 and the secondary-side circuit 14, and the transmission of signals is permitted between the primary-side circuit 13 and the secondary-side circuit 14.

A dielectric breakdown voltage of the signal transmission device 10 is, for example, 2,500 Vrms or more and 7,500 Vrms or less. In one example, the dielectric breakdown voltage of the signal transmission device 10 is about 5,000 Vrms. However, a specific numerical value of the dielectric breakdown voltage of the signal transmission device 10 is not limited thereto and may be changed arbitrarily.

In the example shown in FIG. 1, a ground GND1 of the primary-side circuit 13 and a ground GND2 of the secondary-side circuit 14 are provided independently. Hereinafter, a potential of the ground GND1 of the primary-side circuit 13 is referred to as a first reference potential, and a potential of the ground GND2 of the secondary-side circuit 14 is referred to as a second reference potential. In this case, the first voltage V1 is a voltage from the first reference potential, and the second voltage V2 is a voltage from the second reference potential. The first voltage V1 is, for example, 4.5 V or more and 5.5 V or less, and the second voltage V2 is, for example, 9 V or more and 24 V or less.

Next, a detailed configuration of the signal transmission device 10 will be described. The signal transmission device 10 includes two transformers 15 for transmitting two types of signals, such as the set signal and the reset signal, from the primary-side circuit 13 to the secondary-side circuit 14. More specifically, the signal transmission device 10 includes a transformer 15 used to transmit the set signal from the primary-side circuit 13 to the secondary-side circuit 14, and a transformer 15 used to transmit the reset signal from the primary-side circuit 13 to the secondary-side circuit 14. Hereinafter, for the sake of convenience in explanation, the transformer 15 used to transmit the set signal is referred to as a “transformer 15A,” and the transformer 15 used to transmit the reset signal is referred to as a “transformer 15B.”

The signal transmission device 10 includes a primary-side signal line 16A that connects the primary-side circuit 13 and the transformer 15A, and a primary-side signal line 16B that connects the primary-side circuit 13 and the transformer 15B. Therefore, the primary-side signal line 16A transmits the set signal from the primary-side circuit 13 to the transformer 15A. The primary-side signal line 16B transmits the reset signal from the primary-side circuit 13 to the transformer 15B.

The signal transmission device 10 includes a secondary-side signal line 17A that connects the transformer 15A and the secondary-side circuit 14, and a secondary-side signal line 17B that connects the transformer 15B and the secondary-side circuit 14. Therefore, the secondary-side signal line 17A transmits the set signal from the transformer 15A to the secondary-side circuit 14. The secondary-side signal line 17B transmits the reset signal from the transformer 15B to the secondary-side circuit 14.

The transformer 15A is configured to electrically insulate the primary-side circuit 13 from the secondary-side circuit 14 while transmitting the set signal from the primary-side circuit 13 to the secondary-side circuit 14. The transformer 15B is configured to electrically insulate the primary-side circuit 13 from the secondary-side circuit 14 while transmitting the reset signal from the primary-side circuit 13 to the secondary-side circuit 14.

Each of the transformers 15A and 15B includes a first coil 21 and a second coil 22. The first coil 21 and the second coil 22 are electrically insulated from each other and are configured to be magnetically coupled to each other.

The first coils 21 of the transformers 15A and 15B are electrically connected to the primary-side circuit 13. In one example, a first end of the first coil 21 of the transformer 15A is electrically connected to the primary-side circuit 13 via the primary-side signal line 16A, and a second end of the first coil 21 of the transformer 15A is electrically connected to the ground GND1 of the primary-side circuit 13. A first end of the first coil 21 of the transformer 15B is electrically connected to the primary-side circuit 13 via the primary-side signal line 16B, and a second end of the first coil 21 of the transformer 15B is connected to the ground GND1 of the primary-side circuit 13. Therefore, a potential at the second ends of the first coils 21 of the transformers 15A and 15B becomes the first reference potential. The first reference potential is, for example, 0 V.

The second coils 22 of the transformers 15A and 15B are electrically connected to the secondary-side circuit 14. In one example, the first end of the second coil 22 of the transformer 15A is electrically connected to the secondary-side circuit 14 via the secondary-side signal line 17A, and the second end of the second coil 22 of the transformer 15A is electrically connected to the ground GND2 of the secondary-side circuit 14. The first end of the second coil 22 of the transformer 15B is electrically connected to the secondary-side circuit 14 via the secondary-side signal line 17B, and the second end of the second coil 22 of the transformer 15B is electrically connected to the ground GND2 of the secondary-side circuit 14. Therefore, a potential at the second ends of the second coils 22 of the transformers 15A and 15B becomes the second reference potential. The ground GND2 of the secondary-side circuit 14 is electrically connected, for example, to a source of the switching element in the switching circuit electrically connected to the secondary-side circuit 14.

Meanwhile, depending on how to use the switching circuit, the source of the switching element changes as the switching circuit operates. In this case, the source of the switching element may be, for example, 600 V or higher. Therefore, the ground GND2 of the secondary-side circuit 14, that is, the second reference potential, may be 600 V or more. Thus, the transformers 15A and 15B are required to have dielectric breakdown voltages corresponding to the first reference potential and the second reference potential.

As described above, when the second reference potential is 600 V or more, since the secondary-side circuit 14 operates at a higher potential than the primary-side circuit 13, in other words, the second voltage V2 is higher than the first voltage V1, it may be referred to as a “high voltage circuit.” On the other hand, since the primary-side circuit 13 operates at a lower potential than the secondary-side circuit 14, in other words, the first voltage V1 is lower than the second voltage V2, it may be referred to as a “low voltage circuit.” Therefore, of the transformers 15A and 15B, the first coil 21 electrically connected to the primary-side circuit 13 (the low voltage circuit) may be referred to as a “low voltage coil.” Further, of the transformers 15A and 15B, the second coil 22 electrically connected to the secondary-side circuit 14 (the high voltage circuit) may be referred to as a “high voltage coil.”

FIG. 2 shows an exemplary plan view showing an internal configuration of the signal transmission device 10. In addition, since FIG. 1 shows the circuit configuration of the signal transmission device 10 in a simplified manner, the number of external terminals (primary-side terminals 11 and secondary-side terminals 12) of the signal transmission device 10 of FIG. 2 is larger than the number of external terminals of the signal transmission device 10 of FIG. 1. Further, the number of signal lines (wires W1 to W4 which will be described later) that transmit signals from the primary-side circuit 13 to the secondary-side circuit 14 in the signal transmission device 10 of FIG. 2 is larger than the number of signal lines in the signal transmission device 10 of FIG. 1.

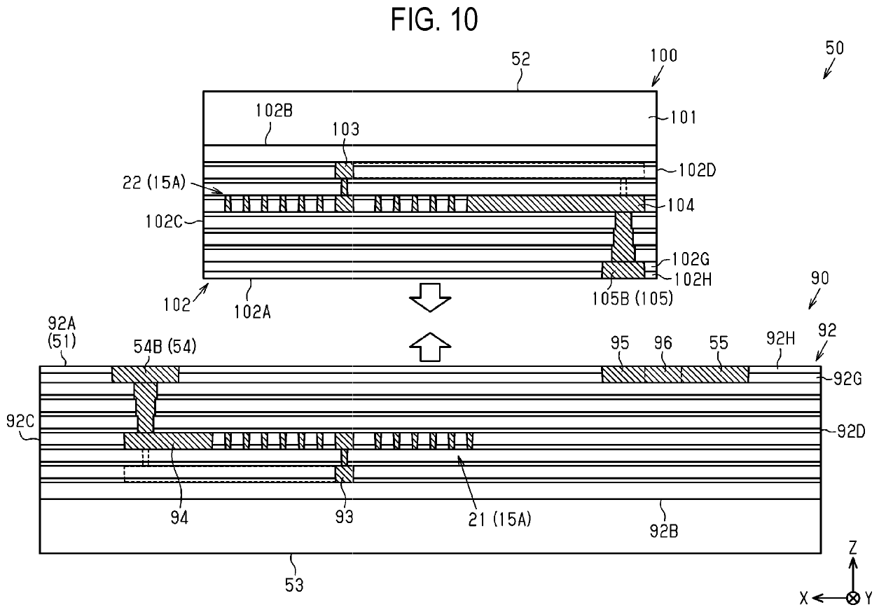

FIG. 3 shows an exemplary cross-sectional view showing an internal configuration of the signal transmission device 10. Note that since FIG. 3 shows the internal configuration of the signal transmission device 10 in a simplified manner, the cross-sectional structures of a first chip 30, a second chip 40, and a transformer chip 50, which will be described later, are simplified. Therefore, the cross-sectional structure of the transformer chip 50 shown in FIG. 3 is different from the cross-sectional structure of the transformer chip 50 shown in FIGS. 10, 12 to 14, and the like.

As shown in FIG. 2, the signal transmission device 10 is a semiconductor device in which a plurality of semiconductor chips are packaged into one. A package format of the signal transmission device 10 is an SO (Small Outline) type, and in the example of FIG. 2, it is an SOP (Small Outline Package). The signal transmission device 10 includes the first chip 30, the second chip 40, and the transformer chip 50 as semiconductor chips. Further, the signal transmission device 10 includes a first lead frame 60 on which the first chip 30 is arranged, a second lead frame 70 on which the second chip 40 is arranged, and a sealing resin 80 for sealing the chips 30, 40, and 50 and portions of the lead frames 60 and 70. The transformer chip 50 is an example of an “insulation chip.” Further, the package format of the signal transmission device 10 may be changed arbitrarily. Further, in FIG. 2, the sealing resin 80 is indicated by a two-dot chain line for the sake of convenience in explaining the internal structure of the signal transmission device 10.

The sealing resin 80 is formed of a material having electrical insulation. In one example, the sealing resin 80 is made of resin containing, for example, epoxy resin. The sealing resin 80 is formed in a rectangular plate shape whose thickness direction is a Z direction. The sealing resin 80 has four resin-side surfaces 81 to 84. The resin-side surfaces 81 and 82 constitute both end surfaces of the sealing resin 80 in an X direction. The resin-side surfaces 83 and 84 constitute both end surfaces of the sealing resin 80 in a Y direction. In the following description, viewing the signal transmission device 10 and its components from the Z direction is referred to as “in a plan view.” Further, the X direction and the Y direction are directions that intersect with the Z direction in a plan view, and are perpendicular to each other. In one example, both the X direction and the Y direction are perpendicular to the Z direction.

Each of the first lead frame 60 and the second lead frame 70 is a conductor and is formed of a material containing, for example, Cu (copper), Fe (iron), or the like. Each of the lead frames 60 and 70 is provided across the inside and outside of the sealing resin 80.

The first lead frame 60 includes a first die pad 61 arranged within the sealing resin 80 and a plurality of first leads 62 arranged across the inside and outside of the sealing resin 80. Each of the first leads 62 constitutes the primary-side terminal 11 (see FIG. 1).

In the example of FIG. 2, both the first chip 30 and the transformer chip 50 are arranged on the first die pad 61. In a plan view, the first die pad 61 is arranged such that its center in the X direction is closer to the resin-side surface 81 than the center of the sealing resin 80 in the X direction. In one example, the first die pad 61 is not exposed from the sealing resin 80. The first die pad 61 is formed in a rectangular flat plate shape whose thickness direction is the Z direction. The shape of the first die pad 61 in a plan view is a rectangular shape in which the Y direction is a longitudinal direction and the X direction is a lateral direction.

The plurality of first leads 62 are arranged to be spaced apart from each other in the Y direction. Of the plurality of first leads 62, each of the first leads 62 arranged at both ends in the Y direction is integrated with the first die pad 61. A portion of each first lead 62 protrudes from the resin-side surface 81 outward of the sealing resin 80.

The second lead frame 70 includes a second die pad 71 arranged within the sealing resin 80 and a plurality of second leads 72 arranged across the inside and outside of the sealing resin 80. Each of the second leads 72 constitutes the secondary-side terminal 12 (see FIG. 1).

In the example of FIG. 2, the second chip 40 is arranged on the second die pad 71. In a plan view, the second die pad 71 is arranged to be closer to the resin-side surface 82 than the first die pad 61 and spaced apart from the first die pad 61 in the X direction. As described above, since the first die pad 61 and the second die pad 71 are arranged in the X direction, it can be said that the X direction is an arrangement direction of the first die pad 61 and the second die pad 71.

In one example, the second die pad 71 is not exposed from the sealing resin 80. The second die pad 71 is formed in a rectangular flat plate shape whose thickness direction is the Z direction. The shape of the second die pad 71 in a plan view is a rectangular shape in which the Y direction is the longitudinal direction and the X direction is the lateral direction. Dimensions of the first die pad 61 and the second die pad 71 in the X direction are set according to the size and number of semiconductor chips to be arranged. Therefore, the dimension in the X direction of the first die pad 61 on which the first chip 30 and the transformer chip 50 are arranged is larger than the dimension in the X direction of the second die pad 71 on which the second chip 40 is arranged.

The plurality of second leads 72 are arranged to be spaced apart from each other in the Y direction. In the example shown in FIG. 2, a pair of second leads 72 among the plurality of second leads 72 are integrated with the second die pad 71. The pair of second leads 72 are the second leads 72 adjacent in the Y direction to each of the second leads 72 arranged at both ends in the Y direction. A portion of each of the second leads 72 protrudes from the resin-side surface 82 outward of the sealing resin 80.

In one example, the number of second leads 72 is the same as the number of first leads 62. As shown in FIG. 2, in a plan view, the plurality of first leads 62 are arranged in a direction (Y direction) perpendicular to the arrangement direction (X direction) of the first die pad 61 and the second die pad 71. Similarly, the plurality of second leads 72 are arranged in the direction (Y direction) perpendicular to the arrangement direction (X direction) of the first die pad 61 and the second die pad 71. Note that the number of first leads 62 and the number of second leads 72 may be changed arbitrarily.

In the example of FIG. 2, the first die pad 61 is supported by a pair of first leads 62 that are integrated with the first die pad 61. The second die pad 71 is supported by a pair of second leads 72 that are integrated with the second die pad 71. Therefore, each of the die pads 61 and 71 is not provided with a hanging lead exposed from the resin-side surfaces 83 and 84. Therefore, an insulation distance between the first lead frame 60 and the second lead frame 70 may be increased.

The first chip 30 and the transformer chip 50 are arranged on the first die pad 61 so as to be spaced apart from each other in the X direction. The second chip 40 is disposed on the opposite side of the first chip 30 with respect to the transformer chip 50 in the X direction. In this way, the first chip 30, the second chip 40, and the transformer chip 50 are arranged to be spaced apart from each other in the X direction. It can be said that the first chip 30, the second chip 40, and the transformer chip 50 are arranged in the same direction as the arrangement direction of the first die pad 61 and the second die pad 71. The first chip 30, the transformer chip 50, and the second chip 40 are arranged in this order from the first lead 62 to the second lead 72 in the X direction. In other words, it can be said that the transformer chip 50 is arranged between the first chip 30 and the second chip 40 in the X direction.

The first chip 30 includes the primary-side circuit 13 shown in FIG. 1. The first chip 30 is formed in a rectangular plate shape whose thickness direction is the Z direction. The shape of the first chip 30 in a plan view is a rectangular shape in which the X direction is the lateral direction and the Y direction is the longitudinal direction. As shown in FIG. 3, the first chip 30 has a chip front surface 31 and a chip back surface 32 facing opposite to each other in the Z direction. The chip back surface 32 of the first chip 30 is bonded to the first die pad 61 by a conductive bonding material SD. For example, a solder paste or an Ag (silver) paste is used as the conductive bonding material SD.

A plurality of first electrode pads 33, a plurality of second electrode pads 34, and a plurality of third electrode pads 35 are formed on the chip front surface 31 of the first chip 30. The first electrode pads 33, the second electrode pads 34, and the third electrode pads 35 are electrically connected to the primary-side circuit 13.

The plurality of first electrode pads 33 are arranged on the chip front surface 31 closer to the first lead 62 than the center of the chip front surface 31 in the X direction. The plurality of first electrode pads 33 are arranged to be spaced apart from each other in the Y direction. The plurality of second electrode pads 34 are arranged at an end closer to the transformer chip 50 of both ends of the chip front surface 31 in the X direction. The plurality of second electrode pads 34 are arranged to be spaced apart from each other in the Y direction. The plurality of third electrode pads 35 are arranged in a distributed manner at both ends of the chip front surface 31 in the Y direction.

As shown in FIG. 3, the first chip 30 includes a substrate 36 on which the primary-side circuit 13 is formed. The substrate 36 is, for example, a semiconductor substrate. An example of the semiconductor substrate is a substrate formed of a material containing Si. A wiring layer 37 is formed on the substrate 36. The substrate 36 constitutes the chip back surface 32, and the wiring layer 37 constitutes the chip front surface 31.

The wiring layer 37 includes, for example, a plurality of insulating films stacked in the Z direction and a metal layer buried in the insulating films. The metal layer constitutes a wiring pattern of the first chip 30. The metal layer electrically connects, for example, the primary-side circuit 13 and each of the electrode pads 33 to 35. That is, each of the electrode pads 33 to 35 is electrically connected to the primary-side circuit 13 via the wiring layer 37. The metal layer is formed of a material containing one or more appropriately selected from the group consisting of, for example, Ti (titanium), TiN (titanium nitride), Au (gold), Ag, Cu, Al (aluminum), and W (tungsten).

As shown in FIG. 2, the second chip 40 includes the secondary-side circuit 14 shown in FIG. 1. The second chip 40 is formed in a rectangular plate shape whose thickness direction is the Z direction. The shape of the second chip 40 in a plan view is a rectangular shape in which the X direction is the lateral direction and the Y direction is the longitudinal direction. As shown in FIG. 3, the second chip 40 has a chip front surface 41 and a chip back surface 42 facing opposite to each other in the Z direction. The chip back surface 42 of the second chip 40 is bonded to the second die pad 71 by a conductive bonding material SD.

A plurality of first electrode pads 43, a plurality of second electrode pads 44, and a plurality of third electrode pads 45 are formed on the chip front surface 41 of the second chip 40. The first electrode pads 43, the second electrode pads 44, and the third electrode pads 45 are electrically connected to the secondary-side circuit 14.

The plurality of first electrode pads 43 are formed at an end closer to the transformer chip 50 of both ends of the chip front surface 41 in the X direction. The plurality of first electrode pads 43 are arranged to be spaced apart from each other in the Y direction. The plurality of second electrode pads 44 are formed at an end closer to the second lead 72 of both ends of the chip front surface 41 in the X direction. The plurality of second electrode pads 44 are arranged to be spaced apart from each other in the Y direction. The plurality of third electrode pads 45 are arranged in a distributed manner at both ends of the chip front surface 41 in the Y direction.

As shown in FIG. 3, the second chip 40 includes a substrate 46 on which the secondary-side circuit 14 is formed. The substrate 46 is, for example, a semiconductor substrate. An example of the semiconductor substrate is a substrate formed of a material containing Si. A wiring layer 47 is formed on the substrate 46. The substrate 46 constitutes the chip back surface 42, and the wiring layer 47 constitutes the chip front surface 41.

The wiring layer 47 includes, for example, a plurality of insulating films stacked in the Z direction and a metal layer buried in the insulating films. The metal layer constitutes a wiring pattern of the second chip 40. The metal layer electrically connects, for example, the secondary-side circuit 14 and each of the electrode pads 43 to 45. That is, each of the electrode pads 43 to 45 is electrically connected to the secondary-side circuit 14 via the wiring layer 47. The metal layer is formed of a material containing one or more appropriately selected from the group consisting of, for example, Ti, TiN, Au, Ag, Cu, Al, and W.

In the first embodiment, the transformer chip 50 is a single chip including the transformers 15A and 15B shown in FIG. 1. That is, the transformer chip 50 is a chip dedicated to the transformers 15A and 15B, which is different from the first chip 30 and the second chip 40.

As shown in FIG. 3, the transformer chip 50 is formed in a convex shape when viewed from the Y direction. The transformer chip 50 has a first chip front surface 51, a second chip front surface 52, and a chip back surface 53 facing opposite to these chip front surfaces 51 and 52. The chip back surface 53 of the transformer chip 50 is bonded to the first die pad 61 by a conductive bonding material SD. The second chip front surface 52 is located on the opposite side of the first die pad 61 with respect to the first chip front surface 51 in the Z direction. In other words, the first chip front surface 51 is located to be closer to the first die pad 61 than the second chip front surface 52 in the Z direction.

As shown in FIGS. 2 and 3, a plurality of first electrode pads 54 and a plurality of second electrode pads 55 are formed on the first chip front surface 51 of the transformer chip 50. The plurality of first electrode pads 54 are formed at an end closer to the first chip 30 of both ends of the first chip front surface 51 in the X direction. The plurality of first electrode pads 54 are arranged to be spaced apart from each other in the Y direction. The plurality of second electrode pads 55 are formed at an end closer to the second chip 40 of both ends of the first chip front surface 51 in the X direction. The plurality of second electrode pads 55 are arranged to be spaced apart from each other in the Y direction.

In order to set the dielectric breakdown voltage of the signal transmission device 10 to a preset dielectric breakdown voltage, it is necessary to separate the first die pad 61 and the second die pad 71 to which the respective lead frames 60 and 70 are closest, from each other. Therefore, in a plan view, a distance between the transformer chip 50 and the second chip 40 in the X direction is larger than a distance between the transformer chip 50 and the first chip 30 in the X direction. On the other hand, since the transformer chip 50 and the first chip 30 are arranged on the first die pad 61, they may be placed to be close to each other. Therefore, it can be said that the transformer chip 50 is arranged to be closer to the first chip 30 than the second chip 40.

A plurality of wires W1 to W4 are connected to each of the first chip 30, the transformer chip 50, and the second chip 40. Each of the wires W1 to W4 is a bonding wire formed by a wire bonding device and is formed of a conductor containing, for example, Au, Al, Cu, or the like.

The first chip 30 is electrically connected to the first lead frame 60 via the wires W1. More specifically, the plurality of first electrode pads 33 and the plurality of third electrode pads 35 of the first chip 30 are electrically connected individually to the plurality of first leads 62 via the wires W1. The plurality of third electrode pads 35 are electrically connected individually to the pair of first leads 62, which are integrated with the first die pad 61 among the plurality of first leads 62, via the wires W1. As a result, the primary-side circuit 13 and the plurality of first leads 62 (the primary-side terminals 11) are electrically connected to each other. In the example of FIG. 2, the pair of first leads 62 integrated with the first die pad 61 constitute a ground terminal, and the primary-side circuit 13 and the first die pad 61 are electrically connected to each other via the wires W1. Therefore, the first die pad 61 has the same potential as the ground GND1 of the primary-side circuit 13.

The second chip 40 is electrically connected to the second lead frame 70 via the wires W4. More specifically, the plurality of second electrode pads 44 and the plurality of third electrode pads 45 of the second chip 40 are electrically connected individually to the plurality of second leads 72 via the wires W4. The plurality of third electrode pads 45 are electrically connected individually to the pair of second leads 72, which are integrated with the second die pad 71 among the plurality of second leads 72, via the wires W4. As a result, the secondary-side circuit 14 and the plurality of second leads 72 (the secondary-side terminals 12) are electrically connected to each other. In the example of FIG. 2, the pair of second leads 72 integrated with the second die pad 71 constitute a ground terminal, and the secondary-side circuit 14 and the second die pad 71 are electrically connected to each other via the wires W4. Therefore, the second die pad 71 has the same potential as the ground GND2 of the secondary-side circuit 14.

The transformer chip 50 is electrically connected to the first chip 30 via the wires W2. Further, the transformer chip 50 is electrically connected to the second chip 40 via the wires W3. More specifically, the plurality of first electrode pads 54 of the transformer chip 50 are electrically connected individually to the plurality of second electrode pads 34 of the first chip 30 via the wires W2. The plurality of second electrode pads 55 of the transformer chip 50 are electrically connected individually to the plurality of first electrode pads 33 of the second chip 40 via the wires W3.

Note that the first coils 21 (see FIG. 3) of the transformers 15A and 15B are electrically connected to the ground GND1 of the primary-side circuit 13 via the wires W2, the first chip 30, and the like. The second coils 22 (see FIG. 3) of the transformers 15A and 15B are electrically connected to the ground GND2 of the secondary-side circuit 14 via the wires W3, the second chip 40, and the like.

### [Configuration of Transformer Chip]

An exemplary configuration of the transformer chip 50 will be described with reference to FIGS. 3 to 11. As shown in FIG. 3, the transformer chip 50 includes a first unit 90 and a second unit 100, which is bonded to the first unit 90. In the following, configurations of the first unit 90 and the second unit 100 will be described, and a configuration of the transformer chip 50, which is a combination of the first unit 90 and the second unit 100, will also be described. Note that the configurations of the first coil 21 and the second coil 22 of the transformer 15B are similar to the configurations of the first coil 21 and the second coil 22 of the transformer 15A. Therefore, in the following, the transformer 15A will be described, and a detailed description of the transformer 15B will be omitted.

### (First Unit)

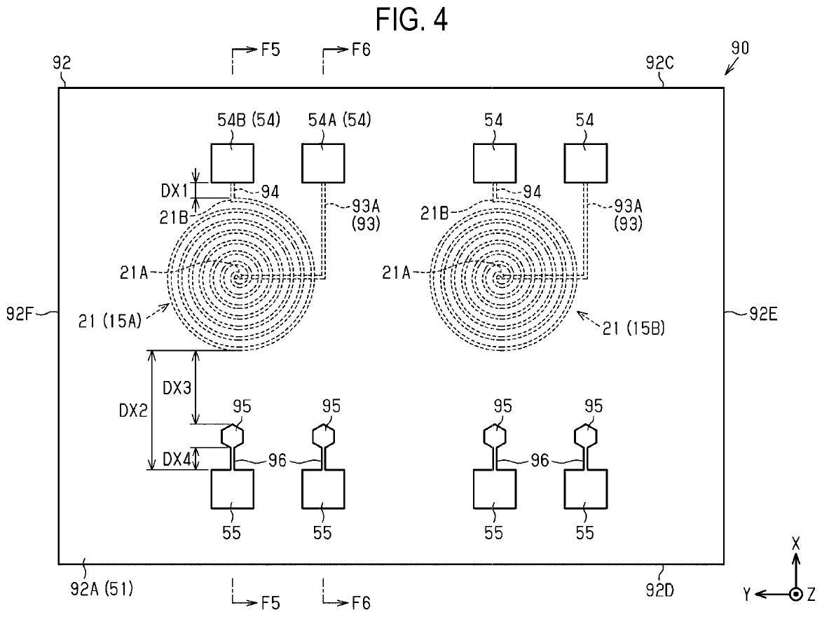

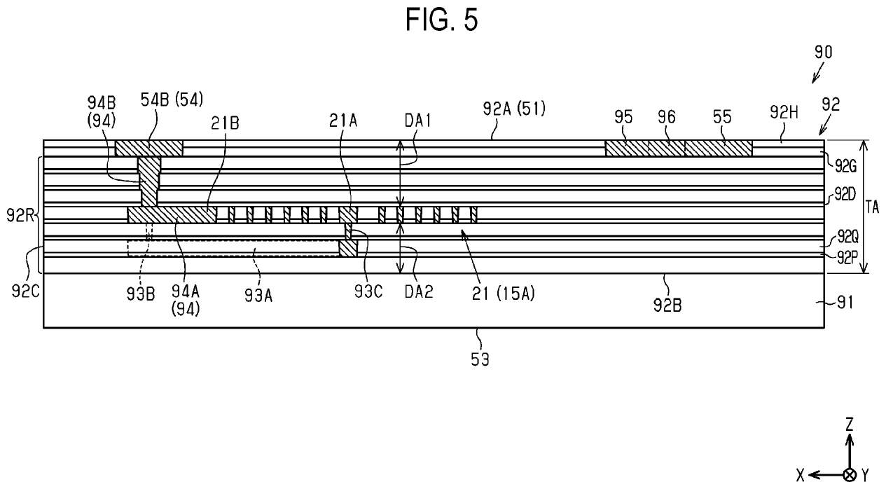

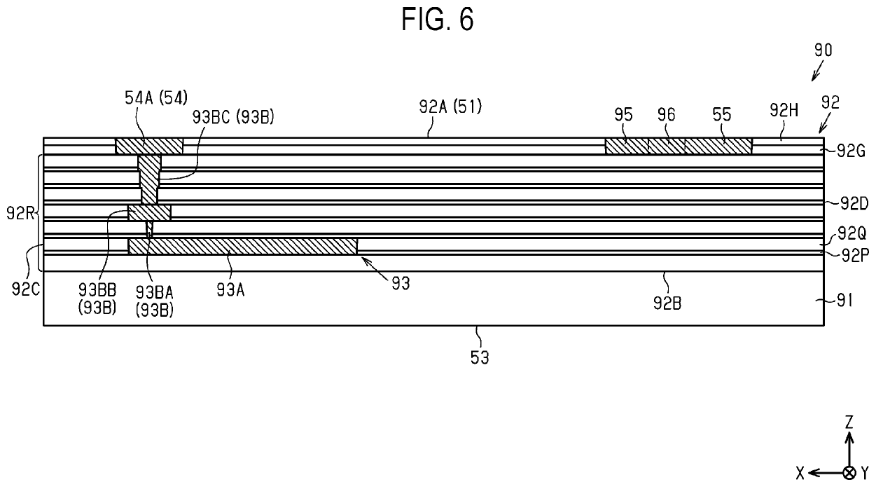

The configuration of the first unit 90 will be described with reference to FIGS. 3 to 6. FIG. 4 shows a planar structure of the first unit 90 of the transformer chip 50. FIG. 5 shows a cross-sectional structure of the first unit 90 taken along line F5-F5 in FIG. 4, mainly showing a cross-sectional structure of the first coil 21 of the transformer 15A. FIG. 6 shows a cross-sectional structure of the first unit 90 taken along line F6-F6 in FIG. 4, mainly showing cross-sectional structures of the first electrode pad 54 and a first connecting portion 93 which will be described later.

As shown in FIG. 3, the first unit 90 is a unit in the transformer chip 50 that is bonded to the first die pad 61 by the conductive bonding material SD. The first unit 90 includes a first substrate 91 and a first element insulating layer 92 formed on the first substrate 91.

The first substrate 91 constitutes the chip back surface 53 of the transformer chip 50. The first substrate 91 is formed in a rectangular plate shape whose thickness direction is the Z direction. The first substrate 91 is formed of, for example, a semiconductor substrate. In one example, the first substrate 91 is formed of a material containing Si. In the first embodiment, the first substrate 91 is a Si substrate. Note that for the first substrate 91, a wide band gap semiconductor or a compound semiconductor may be used as the semiconductor substrate. The wide band gap semiconductor is a semiconductor substrate having a band gap of 2.0 eV or more. The wide band gap semiconductor may be SiC (silicon carbide). The compound semiconductor may be a Group III-V compound semiconductor. The compound semiconductor may include at least one selected from the group consisting of AlN (aluminum nitride), InN (indium nitride), GaN (gallium nitride), and GaAs (gallium arsenide). Further, an insulating substrate formed of a material containing glass or ceramic such as alumina may be used as the first substrate 91.

As shown in FIG. 4, the first element insulating layer 92 is formed in a rectangular shape in which the X direction is the lateral direction and the Y direction is the longitudinal direction in a plan view. The first element insulating layer 92 includes four first element side-surfaces 92C to 92F. The first element side-surfaces 92C and 92D constitute both end surfaces of the first element insulating layer 92 in the X direction. The first element side-surfaces 92E and 92F constitute both end surfaces of the first element insulating layer 92 in the Y direction. In the X direction, the first element side-surface 92C is a side-surface closer to the resin-side surface 81 of the sealing resin 80 in FIG. 2, and the first element side-surface 92D is a side-surface closer to the resin-side surface 82. In the Y direction, the first element side-surface 92E is a side-surface closer to the resin-side surface 83 of the sealing resin 80, and the first element side-surface 92F is a side-surface closer to the resin-side surface 84.

The first unit 90 includes the first coils 21 of the transformers 15A and 15B. More specifically, the first coils 21 of the transformers 15A and 15B are provided in the first element insulating layer 92. These first coils 21 are arranged at the same position in the X direction and spaced apart from each other in the Y direction. The first coil 21 of the transformer 15A is arranged to be closer to the first element side-surface 92F than the first coil 21 of the transformer 15B. Further, these first coils 21 are arranged to be closer to the first element side-surface 92C than the center of the first element insulating layer 92 in the X direction. More specifically, the center of the first coil 21 in the X direction is located to be closer to the first element side-surface 92C than the center of the first element insulating layer 92 in the X direction.

The first electrode pad 54 is arranged to be closer to the first element side-surface 92C than the first coil 21 in the X direction. In the example shown in FIG. 4, four first electrode pads 54 are provided. More specifically, two first electrode pads 54 are provided to correspond to the first coil 21 of the transformer 15A, and two first electrode pads 54 are provided to correspond to the first coil 21 of the transformer 15B.

One of the two first electrode pads 54 corresponding to the first coil 21 of the transformer 15A is arranged at the same position as the first coil 21 in the Y direction. The other of the two first electrode pads 54 is arranged to be closer to the first element side-surface 92E than the first coil 21 in the Y direction.

One of the two first electrode pads 54 corresponding to the first coil 21 of the transformer 15B is arranged at the same position as the first coil 21 in the Y direction. The other of the two first electrode pads 54 is arranged to be closer to the first element side-surface 92E than the first coil 21 in the Y direction. Note that the arrangement positions of the first electrode pads 54 in the Y direction may be changed arbitrarily.

The second electrode pad 55 is arranged at the same position as the first electrode pad 54 in the Z direction. The second electrode pad 55 is arranged to be closer to the first element side-surface 92D than the first coil 21 in the X direction. That is, in a plan view, the first electrode pad 54 and the second electrode pad 55 are arranged in a distributed manner on both sides of the first coil 21 in the X direction. Here, in the present disclosure, the X direction corresponds to a “first direction.”

Four second electrode pads 55 are provided to correspond to the first electrode pads 54. The four second electrode pads 55 are arranged, for example, at the same position as the four first electrode pads 54 in the Y direction. A distance DX2 between the second electrode pad 55 and the first coil 21 in the X direction is larger than a distance DX1 between the first electrode pad 54 and the first coil 21 in the X direction. Note that the numbers of first electrode pads 54 and second electrode pads 55 are not limited to the example shown in FIG. 4, and may be changed arbitrarily.

As shown in FIG. 5, the first element insulating layer 92 includes a plurality of first insulating films 92P and a plurality of second insulating films 92Q. The plurality of first insulating films 92P and the plurality of second insulating films 92Q are alternately stacked one by one in the Z direction. Therefore, it can be said that the Z direction is the thickness direction of the first element insulating layer 92.

Each of the first insulating films 92P is an etching stopper film and is formed of, for example, a material containing at least one selected from the group consisting of SiN (silicon nitride), SiC, and SiCN (nitrogen-doped silicon carbide). Further, the first insulating film 92P may have a function of preventing diffusion of Cu, for example. That is, the first insulating film 92P may be a Cu diffusion prevention film.

Each of the second insulating films 92Q is an interlayer insulating film and is, for example, an oxide film formed of a material containing SiO₂ (silicon oxide). The second insulating film 92Q has a thicker thickness than the first insulating film 92P. The first insulating film 92P has a thickness of, for example, 50 nm or more and less than 1,000 nm. The second insulating film 92Q has a thickness of, for example, 500 nm or more and 5,000 nm or less. In the first embodiment, the first insulating film 92P has a thickness of about 300 nm, and the second insulating film 92Q has a thickness of about 2,000 nm. Note that in order to easily understand the drawings, a ratio between the film thickness of the first insulating film 92P and the film thickness of the second insulating film 92Q in the drawings is different from a ratio between an actual film thickness of the first insulating film 92P and an actual film thickness of the second insulating film 92Q.

The first element insulating layer 92 has a first element front surface 92A and a first element back surface 92B facing opposite to each other in the Z direction. The first element front surface 92A faces the same side as the first chip front surface 51 and the second chip front surface 52 (both see FIG. 3) of the transformer chip 50. The first element front surface 92A constitutes the first chip front surface 51, for example. The first element back surface 92B faces the same side as the chip back surface 53 (see FIG. 3) of the transformer chip 50. The first element back surface 92B is in contact with the first substrate 91. In one example, the first element back surface 92B is constituted with the second insulating film 92Q.

The first element insulating layer 92 includes a protective layer 92G and a passivation layer 92H which are formed on the first element front surface 92A side. The protective layer 92G is a film that protects an insulator 92R which is a laminate of the plurality of first insulating films 92P and the plurality of second insulating films 92Q. The protective layer 92G is formed on the insulator 92R. The protective layer 92G is formed of a material containing, for example, SiO₂. In one example, the protective layer 92G is formed over the entire surface of the insulator 92R in a plan view.

The passivation layer 92H is a surface protection film of the first unit 90. The passivation layer 92H is formed on the protective layer 92G. The passivation layer 92H is formed of a material containing at least one selected from the group consisting of, for example, SiN and SiO₂. In one example, the passivation layer 92H is formed of a material containing SiO₂. In one example, the passivation layer 92H is formed over the entire surface of the protective layer 92G in a plan view.

The first electrode pad 54 and the second electrode pad 55 are formed to be flush with the first element front surface 92A of the first element insulating layer 92. In one example, the first electrode pad 54 and the second electrode pad 55 are provided on the insulator 92R and are covered with the protective layer 92G and the passivation layer 92H. On the other hand, the first electrode pad 54 and the second electrode pad 55 are formed to be flush with the passivation layer 92H. Therefore, the first electrode pad 54 and the second electrode pad 55 are provided on the first element insulating layer 92 so as to be exposed from the first element front surface 92A of the first element insulating layer 92.

The first coil 21 is buried in the first element insulating layer 92 at a position spaced apart from the first element front surface 92A of the first element insulating layer 92 in the Z direction. Further, the first coil 21 is arranged at a position spaced apart from the first element back surface 92B in the Z direction. That is, the first coil 21 is not exposed from the first element insulating layer 92. In the example shown in FIG. 5, the first coil 21 is arranged to be closer to the first element back surface 92B than the first element front surface 92A of the first element insulating layer 92 in the Z direction. In other words, a distance DA1 between the first coil 21 and the first element front surface 92A in the Z direction is larger than a distance DA2 between the first coil 21 and the first element back surface 92B in the Z direction. It can also be said that the first coil 21 is arranged to be closer to the first substrate 91 than the first element front surface 92A in the Z direction. In one example, the distance DA1 may be three times or less than the distance DA2. In one example, the distance DA1 may be twice or less than the distance DA2. Note that the distances DA1 and DA2 may be changed arbitrarily. In one example, the distance DA1 may be larger than twice the distance DA2.

As shown in FIG. 4, the first coil 21 is formed in a spiral shape in a plan view. The first coil 21 includes a first end portion 21A and a second end portion 21B. The first end portion 21A constitutes an inner end of a winding portion of the first coil 21 in a plan view. The second end portion 21B constitutes an outer end of the winding portion of the first coil 21 in a plan view. Note that the number of turns of the first coil 21 may be arbitrarily changed depending on electrical characteristics of the transformer chip 50.

The first coil 21 is made of a material including one or more appropriately selected from the group consisting of, for example, Ti, TiN, Au, Ag, Cu, Al, and W. In one example, the first coil 21 is formed of a material containing Cu.

The first unit 90 includes a first connecting portion 93 connected to the first end portion 21A of the first coil 21 and a second connecting portion 94 connected to the second end portion 21B of the first coil 21. In the following description, the two first electrode pads 54 corresponding to the transformer 15A shown in FIG. 4 are referred to as a “first electrode pad 54A” and a “first electrode pad 54B.”

As shown in FIG. 4, the first connecting portion 93 is connected to the first electrode pad 54A. That is, the first connecting portion 93 electrically connects the first end portion 21A of the first coil 21 and the first electrode pad 54A. The first connecting portion 93 is buried in the first element insulating layer 92. That is, the first coil 21 and the first electrode pad 54A are electrically connected to each other within the first element insulating layer 92.

As shown in FIGS. 4 and 6, the first connecting portion 93 includes a first wiring layer 93A, a first connection wiring 93B, and a via 93C. As shown in FIGS. 5 and 6, the first wiring layer 93A is arranged to be closer to the first element back surface 92B than the first coil 21 in the Z direction. It can be said that the first wiring layer 93A is arranged between the first coil 21 and the first element back surface 92B in the Z direction. As shown in FIG. 4, the first wiring layer 93A includes a first portion extending in the Y direction from the first end portion 21A of the first coil 21 in a plan view, and a second portion extending in the X direction from the first portion toward the first electrode pad 54A. In one example, the first portion and the second portion are integrated. The second portion is arranged outward from the winding portion of the first coil 21 in the X direction.

As shown in FIG. 6, the first connection wiring 93B electrically connects the first wiring layer 93A and the first electrode pad 54A. The first connection wiring 93B is provided at a position overlapping both the first electrode pad 54A and the first wiring layer 93A in a plan view. The first connection wiring 93B is formed as a via extending in the Z direction. In the example shown in FIG. 6, the first connection wiring 93B includes a first via 93BA, an intermediate wiring layer 93BB, and a second via 93BC. The first via 93BA is connected to the first wiring layer 93A. The intermediate wiring layer 93BB is formed on the first via 93BA. The intermediate wiring layer 93BB is connected to the first via 93BA. The second via 93BC is formed on the intermediate wiring layer 93BB. The second via 93BC connects the first electrode pad 54A and the intermediate wiring layer 93BB. A length of the second via 93BC in the Z direction is longer than a length of the first via 93BA in the Z direction.

As shown in FIG. 5, the via 93C electrically connects the first wiring layer 93A and the first end portion 21A of the first coil 21. The via 93C is arranged at a position overlapping both the first end portion 21A of the first coil 21 and the first wiring layer 93A in a plan view. The first wiring layer 93A, the first connection wiring 93B, and the via 93C are made of a material containing one or more appropriately selected from the group consisting of, for example, Ti, TiN, Au, Ag, Cu, Al, and W. In one example, the first wiring layer 93A may be formed of the same material as the first coil 21. In one example, the first connection wiring 93B and the via 93C may be formed of a different material from the first coil 21.

As shown in FIG. 4, the second connecting portion 94 is connected to the first electrode pad 54B. That is, the second connecting portion 94 electrically connects the second end portion 21B of the first coil 21 and the first electrode pad 54B. The second connecting portion 94 is buried in the first element insulating layer 92. That is, the first coil 21 and the first electrode pad 54B are electrically connected to each other within the first element insulating layer 92.

As shown in FIGS. 4 and 5, the second connecting portion 94 includes a second wiring layer 94A and a second connection wiring 94B. The second wiring layer 94A is arranged at the same position as the first coil 21 in the Z direction. That is, the second wiring layer 94A is arranged to be closer to the first element front surface 92A than the first wiring layer 93A. The second wiring layer 94A extends in the X direction from the second end portion 21B of the first coil 21 toward the first electrode pad 54B in a plan view.

Note that the position of the second wiring layer 94A in the Z direction may be changed arbitrarily. In one example, the second wiring layer 94A may be arranged at the same position as the first wiring layer 93A in the Z direction. That is, the second wiring layer 94A may be arranged to be closer to the first element back surface 92B than the first coil 21 in the Z direction.

The second connection wiring 94B electrically connects the second wiring layer 94A and the first electrode pad 54B. The second connection wiring 94B is provided at a position overlapping both the first electrode pad 54B and the second wiring layer 94A in a plan view. The second connection wiring 94B is formed as a via extending in the Z direction. The second wiring layer 94A and the second connection wiring 94B are made of a material containing one or more appropriately selected from the group consisting of, for example, Ti, TiN, Au, Ag, Cu, Al, and W. In one example, the second wiring layer 94A may be formed of the same material as the first coil 21. In one example, the second connection wiring 94B may be formed of a different material from the first coil 21.

Here, in the present disclosure, both the first wiring layer 93A of the first connecting portion 93 and the second wiring layer 94A of the second connecting portion 94 correspond to a “wiring layer of the first unit.” Both the first connection wiring 93B of the first connecting portion 93 and the second connection wiring 94B of the second connecting portion 94 correspond to a “connection wiring of the first unit.”

As shown in FIGS. 4 and 5, the first unit 90 includes a first metal terminal 95 and a connection wiring 96. The first metal terminal 95 and the connection wiring 96 are provided to correspond to the number of second electrode pads 55. In the example shown in FIG. 4, since two second electrode pads 55 are provided, two first metal terminals 95 and two connection wirings 96 are provided to correspond thereto.

The first metal terminal 95 is provided on the first element insulating layer 92 so as to be exposed from the first element front surface 92A of the first element insulating layer 92. The first metal terminal 95 is arranged at a different position from the first coil 21 in a plan view. The first metal terminal 95 is arranged outward from the first coil 21 in a plan view. More specifically, the first metal terminal 95 is arranged to be closer to the first element side-surface 92D than the first coil 21 in a plan view. On the other hand, the first metal terminal 95 is arranged to be closer to the first element side-surface 92C than the second electrode pad 55 in a plan view. That is, the first metal terminal 95 is arranged between the first coil 21 and the second electrode pad 55 in the X direction in a plan view. The first metal terminal 95 is provided at the same position as the second electrode pad 55 in the Z direction. The first metal terminal 95 is arranged to be closer to the second electrode pad 55 in the X direction with respect to the center between the first coil 21 and the second electrode pad 55 in the X direction.

In one example, in order to ensure the electrical insulation between the first coil 21 and the first metal terminal 95, it is preferable that the first metal terminal 95 is separated from the first coil 21 by a relatively large distance. Therefore, in a plan view, a distance DX3 between the first metal terminal 95 and the first coil 21 in the X direction is larger than a distance DX4 between the first metal terminal 95 and the second electrode pad 55 in the X direction. The distance DX3 is ½ or more of the distance DX2. The distance DX3 may be larger than ½ of the distance DX2.

A shape of the first metal terminal 95 in a plan view is a polygonal shape. In one example, the first metal terminal 95 has a hexagonal shape in a plan view. In a plan view, an area of the first metal terminal 95 is smaller than an area of the second electrode pad 55. Note that the shape of the first metal terminal 95 in a plan view may be changed arbitrarily and may be, for example, rectangular or circular.

The connection wiring 96 connects the first metal terminal 95 and the second electrode pad 55. As a result, the first metal terminal 95, the connection wiring 96, and the second electrode pad 55 are electrically connected to each other. The connection wiring 96 extends in the X direction in a plan view. The connection wiring 96 is arranged at the same position as both the first metal terminal 95 and the second electrode pad 55 in the Z direction.

The first metal terminal 95, the connection wiring 96, and the second electrode pad 55 are not electrically connected to the first coil 21. Therefore, in the first unit 90, the first metal terminal 95, the connection wiring 96, and the second electrode pad 55 are in an electrically floating state.

As shown in FIG. 5, since the first metal terminal 95 and the connection wiring 96 are provided at the same position as the second electrode pad 55 in the Z direction, it can be said that they are provided on the insulator 92R. Further, the first metal terminal 95 and the connection wiring 96 are covered with the protective layer 92G and the passivation layer 92H. On the other hand, the first metal terminal 95 and the connection wiring 96 are provided to be flush with the passivation layer 92H. That is, the first metal terminal 95 and the connection wiring 96 are provided in the first element insulating layer 92 so as to be exposed from the first element front surface 92A of the first element insulating layer 92.

The first metal terminal 95 and the connection wiring 96 are made of a material containing one or more appropriately selected from the group consisting of, for example, Ti, TiN, Au, Ag, Cu, Al, and W. In one example, the first metal terminal 95 is formed of a material containing Cu. The connection wiring 96 and the second electrode pad 55 may be formed of the same material as the first metal terminal 95, for example. In this way, the first metal terminal 95, the connection wiring 96, and the second electrode pad 55 may be integrated.

### (Second Unit)

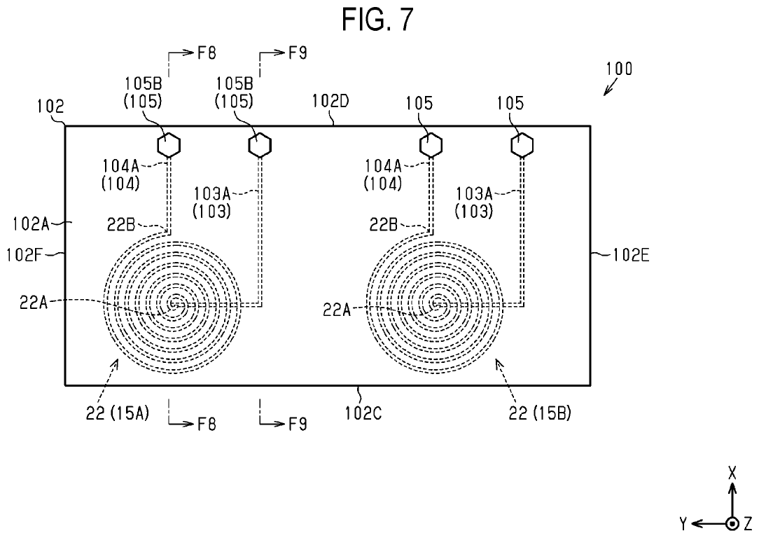

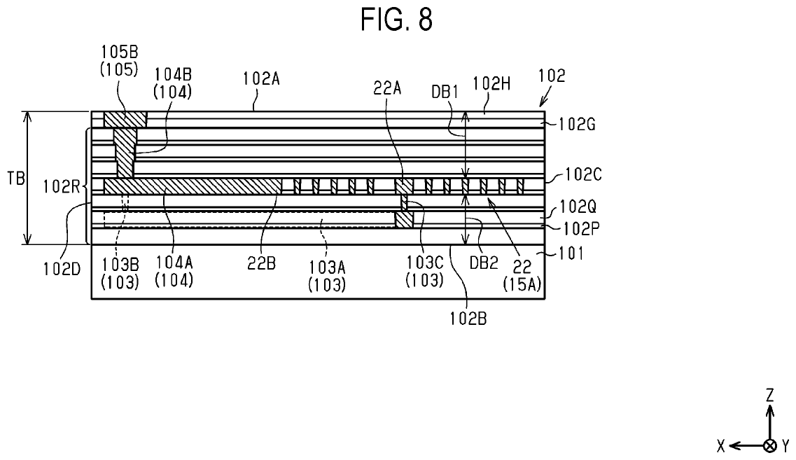

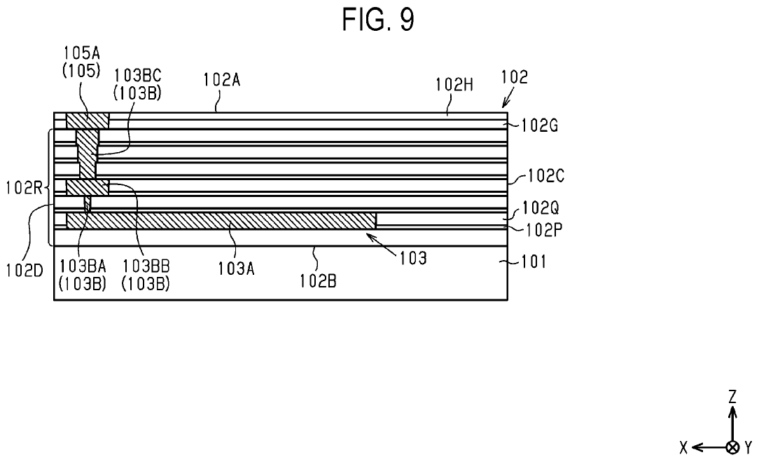

A configuration of the second unit 100 will be described with reference to FIGS. 3 and 7 to 9. FIG. 7 shows a planar structure of the second unit 100 of the transformer chip 50. FIG. 8 is a cross-sectional structure of the second unit 100 taken along line F8-F8 in FIG. 7, mainly showing a cross-sectional structure of the second coil 22 of the transformer 15A. FIG. 9 is a cross-sectional structure of the second unit 100 taken along line F9-F9 in FIG. 7, mainly showing cross-sectional structures of a second metal terminal 105 and a first connecting portion 103 which will be described later.

As shown in FIG. 3, the second unit 100 is a unit in the transformer chip 50 that is disposed on the opposite side of the first die pad 61 with respect to the first unit 90. The second unit 100 includes a second substrate 101 and a second element insulating layer 102 formed on the second substrate 101.

The second substrate 101 constitutes the second chip front surface 52 of the transformer chip 50. The second substrate 101 is formed in a rectangular plate shape whose thickness direction is the Z direction. The second substrate 101 is formed of, for example, a semiconductor substrate. In one example, like the first substrate 91, the second substrate 101 is a semiconductor substrate formed of a material containing Si. In the first embodiment, the second substrate 101 is a Si substrate. Note that for the second substrate 101, a wide band gap semiconductor or a compound semiconductor may be used as the semiconductor substrate. Further, an insulating substrate formed of a material containing glass or ceramic such as alumina may be used as the second substrate 101.

As shown in FIG. 7, the second element insulating layer 102 is formed in a rectangular shape in which the X direction is the lateral direction and the Y direction is the longitudinal direction in a plan view. The second element insulating layer 102 includes four second element side-surfaces 102C to 102F. The second element side-surfaces 102C and 102D constitute both end surfaces of the second element insulating layer 102 in the X direction. The second element side-surfaces 102E and 102F constitute both end surfaces of the second element insulating layer 102 in the Y direction. In the X direction, the second element side-surface 102C is a side-surface closer to the resin-side surface 81 of the sealing resin 80 in FIG. 2, and the second element side-surface 102D is a side-surface closer to the resin-side surface 82. In the Y direction, the second element side-surface 102E is a side-surface closer to the resin-side surface 83 of the sealing resin 80, and the second element side-surface 102F is a side-surface closer to the resin-side surface 84.

The second unit 100 includes the second coils 22 of the transformers 15A and 15B. More specifically, the second coils 22 of the transformers 15A and 15B are provided in the second element insulating layer 102.

The second coil 22 of the transformer 15A and the second coil 22 of the transformer 15B are arranged at the same position in the X direction and spaced apart from each other in the Y direction. The second coil 22 of the transformer 15A is arranged to be closer to the second element side-surface 102F than the second coil 22 of the transformer 15B. Further, these second coils 22 are arranged to be closer to the second element side-surface 102C than the center of the second element insulating layer 102 in the X direction. More specifically, the center of the second coil 22 in the X direction is located to be closer to the second element side-surface 102C than the center of the second element insulating layer 102 in the X direction.

As shown in FIG. 8, the second element insulating layer 102 includes a plurality of first insulating films 102P and a plurality of second insulating films 102Q. The plurality of first insulating films 102P and the plurality of second insulating films 102Q are alternately stacked one by one in the Z direction. Therefore, it can be said that the Z direction is the thickness direction of the second element insulating layer 102.

Each of the first insulating films 102P is an etching stopper film and is formed of, for example, a material containing at least one selected from the group consisting of SiN, SiC, and SiCN. Further, the first insulating film 102P may have a function of preventing diffusion of Cu, for example. That is, the first insulating film 102P may be a Cu diffusion prevention film.

Each of the second insulating films 102Q is an interlayer insulating film and is, for example, an oxide film formed of a material containing SiO₂. The second insulating film 102Q has a thicker thickness than the first insulating film 102P. In one example, the second insulating film 102Q may have the same thickness as the second insulating film 92Q (see FIG. 5) of the first element insulating layer 92. In one example, the first insulating film 102P may have the same thickness as the first insulating film 92P (see FIG. 5) of the first element insulating layer 92. The first insulating film 102P has a thickness of, for example, 50 nm or more and less than 1,000 nm. The second insulating film 102Q has a thickness of, for example, 500 nm or more and 5,000 nm or less. In the first embodiment, the first insulating film 102P has a thickness of about 300 nm, and the second insulating film 102Q has a thickness of about 2,000 nm. Further, in one example, the number of first insulating films 102P may be the same as the number of first insulating films 92P of the first element insulating layer 92. The number of second insulating films 102Q may be the same as the number of second insulating films 92Q of the first element insulating layer 92. As described above, the thickness of an insulator 102R, which is a laminate of plurality of first insulating films 102P and the plurality of second insulating films 102Q, may be equal to the thickness of the insulator 92R (see FIG. 5). Note that in order to easily understand the drawings, a ratio between the film thickness of the first insulating film 102P and the film thickness of the second insulating film 102Q in the drawings is different from a ratio between an actual film thickness of the first insulating film 102P and an actual film thickness of the second insulating film 102Q.

The second element insulating layer 102 has a second element front surface 102A and a second element back surface 102B facing opposite to each other in the Z direction. The second element front surface 102A faces the same side as the chip back surface 53 (see FIG. 3) of the transformer chip 50. The second element back surface 102B faces the same side as the first chip front surface 51 and the second chip front surface 52 (both see FIG. 3) of the transformer chip 50. The second element back surface 102B is in contact with the second substrate 101. In one example, the second element back surface 102B is constituted with the second insulating film 102Q.

The second element insulating layer 102 includes a protective layer 102G and a passivation layer 102H formed on the second element front surface 102A side. The protective layer 102G is a film that protects the insulator 102R. The protective layer 102G is formed on the insulator 102R. The protective layer 102G is formed of a material containing, for example, SiO₂. In one example, the protective layer 102G is formed over the entire surface of the insulator 102R in a plan view.

The passivation layer 102H is a surface protection film of the second unit 100. The passivation layer 102H is formed on the protective layer 102G. The passivation layer 102H is formed of a material containing at least one selected from the group consisting of, for example, SiN and SiO₂. The passivation layer 102H is formed of a material containing, for example, SiO₂. In one example, the passivation layer 102H is formed over the entire surface of the protective layer 102G in a plan view.

The second coil 22 is buried in the second element insulating layer 102 at a position spaced apart from the second element front surface 102A of the second element insulating layer 102 in the Z direction. Further, the second coil 22 is arranged at a position spaced apart from the second element back surface 102B in the Z direction. That is, the second coil 22 is not exposed from the second element insulating layer 102. In the example shown in FIG. 8, the second coil 22 is arranged to be closer to the second element back surface 102B than the second element front surface 102A of the second element insulating layer 102 in the Z direction. In other words, a distance DB1 between the second coil 22 and the second element front surface 102A in the Z direction is larger than a distance DB2 between the second coil 22 and the second element back surface 102B in the Z direction. It can also be said that the second coil 22 is arranged to be closer to the second substrate 101 than the second element front surface 102A in the Z direction. In one example, the distance DB1 may be three times or less than the distance DB2. In one example, the distance DB1 may be twice or less than the distance DB2. Note that the relationship between the distance DB1 and the distance DB2 may be changed arbitrarily. In one example, the distance DB1 may be larger than twice the distance DB2.

As shown in FIG. 7, the second coil 22 is formed in a spiral shape in a plan view. The second coil 22 includes a first end portion 22A and a second end portion 22B. The first end portion 22A constitutes an inner end of a winding portion of the second coil 22 in a plan view. The second end portion 22B constitutes an outer end of the winding portion of the second coil 22 in a plan view. Note that the number of turns of the second coil 22 may be arbitrarily changed according to electrical characteristics of the transformer chip 50. The second coil 22 is made of a material containing one or more appropriately selected from the group consisting of, for example, Ti, TiN, Au, Ag, Cu, Al, and W. In one example, the second coil 22 is formed of a material containing Cu. That is, the second coil 22 may be formed of the same material as the first coil 21 (see FIG. 4). Note that the material constituting the second coil 22 may be changed arbitrarily. In one example, the second coil 22 may be formed of a different material than the first coil 21.

The second unit 100 includes a first connecting portion 103 connected to the first end portion 22A of the second coil 22, a second connecting portion 104 connected to the second end portion 22B of the second coil 22, and a second metal terminal 105. Two second metal terminals 105 are provided for one second coil 22. In the first embodiment, the second unit 100 includes four second metal terminals 105 because two second coils, the second coil 22 of the transformer 15A and the second coil 22 of the transformer 15B, are provided. In the following description, the two second metal terminals 105 corresponding to the transformer 15A shown in FIG. 7 are referred to as a “second metal terminal 105A” and a “second metal terminal 105B.”

As shown in FIG. 7, the second metal terminals 105A and 105B are provided on the second element insulating layer 102 so as to be exposed from the second element front surface 102A of the second element insulating layer 102. The second metal terminals 105A and 105B are arranged at different positions from the second coil 22 in a plan view. The second metal terminals 105A and 105B are arranged outward from the second coil 22 in a plan view. In the example shown in FIG. 7, the second metal terminals 105A and 105B are arranged to be closer to the second element side-surface 102D than the second coil 22 in a plan view. More specifically, the second metal terminals 105A and 105B are arranged at an end portion, which is closer to the second element side-surface 102D, of both end portions of the second element front surface 102A in the X direction. The second metal terminals 105A and 105B are arranged at the same position in the X direction and spaced apart from each other in the Y direction.

As shown in FIGS. 8 and 9, the second metal terminals 105A and 105B are formed to be flush with the second element front surface 102A of the second element insulating layer 102. In one example, the second metal terminals 105A and 105B are provided on the insulator 102R and are covered with the protective layer 102G and the passivation layer 102H. On the other hand, the second metal terminals 105A and 105B are formed to be flush with the passivation layer 102H.

As shown in FIG. 7, the shape of the second metal terminals 105A and 105B in a plan view is a polygonal shape. In one example, the second metal terminals 105A and 105B have a hexagonal shape in a plan view. Note that the shape of the second metal terminals 105A and 105B in a plan view may be changed arbitrarily and may be, for example, rectangular or circular.

The second metal terminal 105 (105A and 105B) are made of a material containing one or more appropriately selected from the group consisting of, for example, Ti, TiN, Au, Ag, Cu, Al, and W. In one example, the second metal terminal 105 is formed of a material containing Cu.

As shown in FIG. 9, the first connecting portion 103 is connected to the second metal terminal 105A. That is, the first connecting portion 103 electrically connects the first end portion 22A (see FIG. 7) of the second coil 22 and the second metal terminal 105A. The first connecting portion 103 is buried in the second element insulating layer 102. That is, the second coil 22 and the second metal terminal 105A are electrically connected to each other within the second element insulating layer 102.

As shown in FIGS. 8 and 9, the first connecting portion 103 includes a first wiring layer 103A, a first connection wiring 103B, and a via 103C. The first wiring layer 103A is arranged to be closer to the second element back surface 102B than the second coil 22 in the Z direction. It can also be said that the first wiring layer 103A is arranged between the second coil 22 and the second element back surface 102B in the Z direction. As shown in FIG. 7, the first wiring layer 103A includes a first portion extending in the Y direction from the first end portion 22A of the second coil 22 in a plan view, and a second portion extending in the X direction from the first portion toward the second metal terminal 105A. In one example, the first portion and the second portion are integrated. The second portion is arranged outward from the winding portion of the second coil 22 in the X direction.

As shown in FIG. 9, the first connection wiring 103B electrically connects the first wiring layer 103A and the second metal terminal 105A. The first connection wiring 103B is provided at a position overlapping both the second metal terminal 105A and the first wiring layer 103A in a plan view. The first connection wiring 103B is formed as a via extending in the Z direction. In the example shown in FIG. 9, the first connection wiring 103B includes a first via 103BA, an intermediate wiring layer 103BB, and a second via 103BC. The first via 103BA is connected to the first wiring layer 103A. The intermediate wiring layer 103BB is formed on the first via 103BA. The intermediate wiring layer 103BB is connected to the first via 103BA. The second via 103BC is formed on the intermediate wiring layer 103BB. The second via 103BC connects the second metal terminal 105B and the intermediate wiring layer 103BB. A length of the second via 103BC in the Z direction is longer than a length of the first via 103BA in the Z direction.

As shown in FIG. 8, the via 103C electrically connects the first wiring layer 103A and the first end portion 22A of the second coil 22. The via 103C is arranged at a position overlapping both the first end portion 22A of the second coil 22 and the first wiring layer 103A in a plan view. The first wiring layer 103A, the first connection wiring 103B, and the via 103C are made of a material containing one or more appropriately selected from the group consisting of, for example, Ti, TiN, Au, Ag, Cu, Al, and W. In one example, the first wiring layer 103A may be formed of the same material as the second coil 22. In one example, the first connection wiring 103B and the via 103C may be formed of a different material from the second coil 22.

As shown in FIG. 7, the second connecting portion 104 is connected to the second metal terminal 105B. That is, the second connecting portion 104 electrically connects the second end portion 22B of the second coil 22 and the second metal terminal 105B. The second connecting portion 104 is buried in the second element insulating layer 102. That is, the second coil 22 and the second metal terminal 105B are electrically connected to each other within the second element insulating layer 102.

As shown in FIGS. 7 and 8, the second connecting portion 104 includes a second wiring layer 104A and a second connection wiring 104B. The second wiring layer 104A is arranged at the same position as the second coil 22 in the Z direction. That is, the second wiring layer 104A is arranged to be closer to the second element front surface 102A than the first wiring layer 103A. The second wiring layer 104A extends in the X direction toward the second metal terminal 105B in a plan view.

Note that the position of the second wiring layer 104A in the Z direction may be changed arbitrarily. In one example, the second wiring layer 104A may be arranged at the same position as the first wiring layer 103A in the Z direction. That is, the second wiring layer 104A may be arranged to be closer to the second element back surface 102B than the second coil 22 in the Z direction.

The second connection wiring 104B electrically connects the second wiring layer 104A and the second metal terminal 105B. The second connection wiring 104B is provided at a position overlapping both the second metal terminal 105B and the second wiring layer 104A in a plan view. The second connection wiring 104B is formed as a via extending in the Z direction. The second wiring layer 104A and the second connection wiring 104B are made of a material containing one or more appropriately selected from the group consisting of, for example, Ti, TiN, Au, Ag, Cu, Al, and W. In one example, the second wiring layer 104A may be formed of the same material as the second coil 22. In one example, the second connection wiring 104B may be formed of a different material from the second coil 22.

Here, in the present disclosure, both the first wiring layer 103A of the first connecting portion 103 and the second wiring layer 104A of the second connecting portion 104 correspond to a “wiring layer of the second unit.” Both the first connection wiring 103B of the first connecting portion 103 and the second connection wiring 104B of the second connecting portion 104 correspond to a “connection wiring of the second unit.”

### (Transformer Chip)

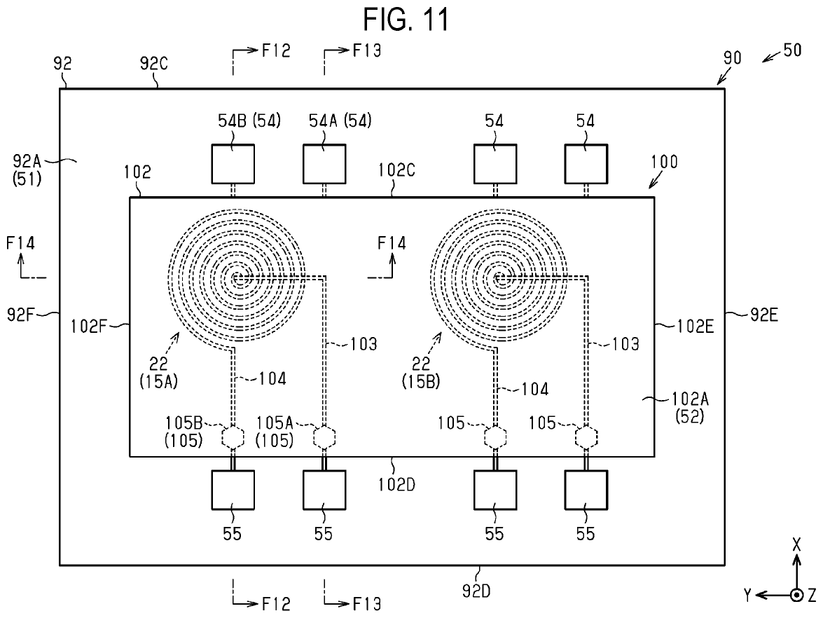

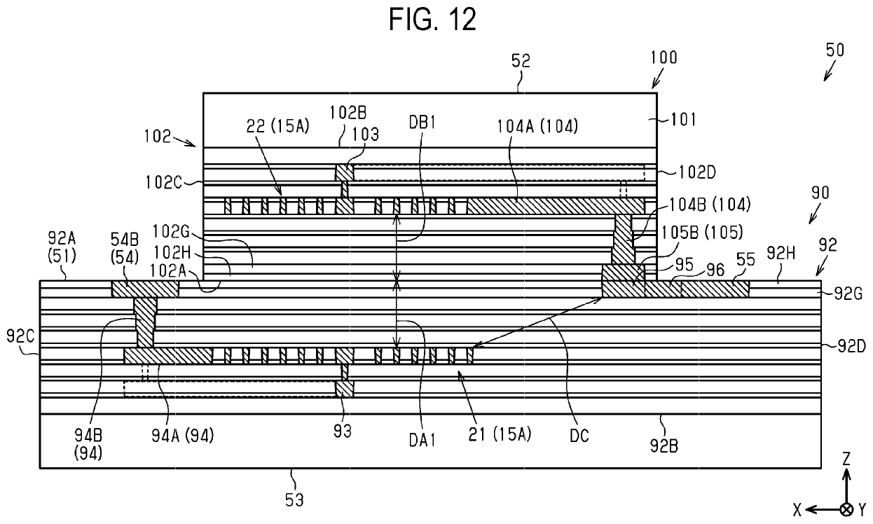

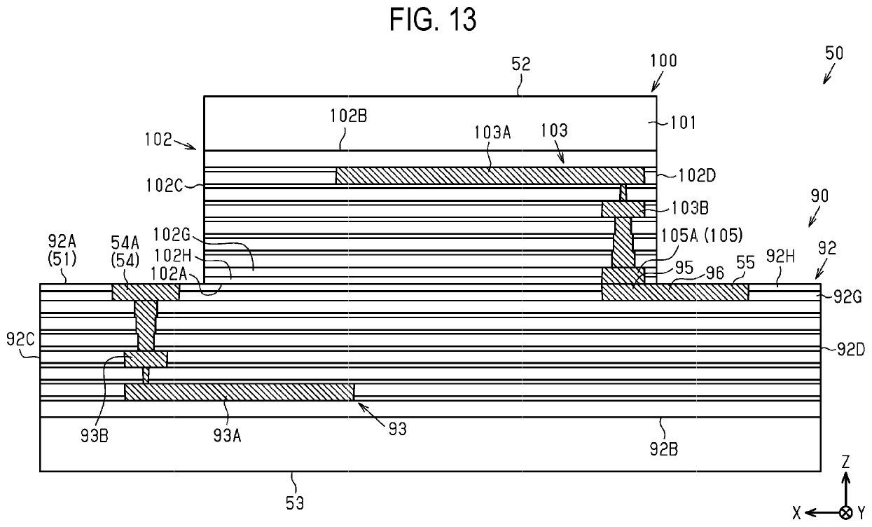

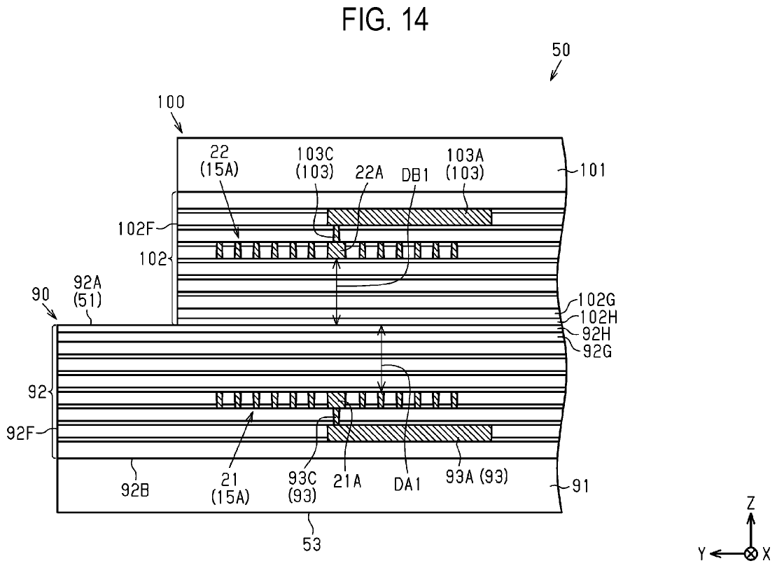

A configuration of the transformer chip 50 will be described with reference to FIGS. 10 to 14. FIG. 10 shows a schematic cross-sectional structure showing a process of bonding the first unit 90 and the second unit 100. FIG. 11 shows a planar structure of the transformer chip 50. FIG. 12 shows a cross-sectional structure of the transformer chip 50 taken along line F12-F12 in FIG. 11, mainly showing cross-sectional structures of the first coil 21 and the second coil 22 of the transformer 15A. FIG. 13 shows a cross-sectional structure of the transformer chip 50 taken along line F13-F13 in FIG. 11, mainly showing cross-sectional structures of the first connecting portions 93 and 103 of the transformer 15A. FIG. 14 shows a cross-sectional structure of the transformer chip 50 taken along line F14-F14 in FIG. 11, mainly showing cross-sectional structures of the first coil 21 and the second coil 22 of the transformer 15A in a direction different from that in FIG. 12.

As shown in FIG. 10, the second unit 100 is arranged such that the second element front surface 102A of the second element insulating layer 102 faces the first element front surface 92A of the first element insulating layer 92 of the first unit 90. Therefore, the second element front surface 102A constitutes, for example, a bonding surface of the second unit 100 with the first unit 90. The first element front surface 92A of the first unit 90, which faces the second element front surface 102A, constitutes a bonding surface of the first unit 90 with the second unit 100. Further, the second substrate 101 of the second unit 100 is arranged on the opposite side of the first unit 90 with respect to the second element insulating layer 102 in the Z direction. Therefore, the second substrate 101 constitutes the second chip front surface 52 of the transformer chip 50.

As shown in FIG. 11, in the second unit 100, the second element side-surface 102D is arranged to be closer to the first element side-surface 92D of the first unit 90 in the X direction, and the second element side-surface 102C is arranged to be closer to the first element side-surface 92C of the first unit 90. Therefore, the second metal terminal 105 of the second unit 100 is arranged to face the first metal terminal 95 (see FIG. 12) of the first unit 90 in the Z direction.

As shown in FIG. 12, in a state where the second unit 100 is bonded to the first unit 90 (hereinafter referred to as a “unit bonding state”), the second element front surface 102A of the second element insulating layer 102 is in contact with the first element front surface 92A of the first element insulating layer 92. In one example, the second element front surface 102A is in contact with the first element front surface 92A over its entire surface. In the unit bonding state, in the first unit 90 and the second unit 100, the first element front surface 92A and the second element front surface 102A are in direct contact with each other and are also bonded to each other.

As shown in FIGS. 11 and 12, the second unit 100 is smaller than the first unit 90 in a plan view. More specifically, in a plan view, the dimension in the X direction of the second unit 100 is smaller than the dimension in the X direction of the first unit 90, and the dimension in the Y direction of the second unit 100 is smaller than the dimension in the Y direction of the first unit 90. Further, in a plan view, the second unit 100 is arranged at the center of the first unit 90 in the X direction and the Y direction. Therefore, the first element front surface 92A of the first element insulating layer 92 includes a rectangular frame-shaped exposure region surrounding the second unit 100 in a plan view. This exposure region constitutes the first chip front surface 51 of the transformer chip 50.

As shown in FIG. 11, the first electrode pad 54 and the second electrode pad 55 are provided at different positions from the second unit 100 in a plan view. More specifically, in a plan view, the first electrode pad 54 is arranged to be closer to the first element side-surface 92C than the second unit 100. In a plan view, the second electrode pad 55 is arranged to be closer to the first element side-surface 92D than the second unit 100.

As shown in FIG. 13, in the unit bonding state, the second metal terminal 105A of the second unit 100 is bonded to the first metal terminal 95 of the second electrode pad 55 of the first unit 90. More specifically, the first metal terminal 95 and the second metal terminal 105A are in direct contact with each other in the unit bonding state and are also bonded to each other. As a result, the first metal terminal 95 and the second metal terminal 105A are electrically connected to each other so that the first end portion 22A of the second coil 22 and the second electrode pad 55 are electrically connected to each other.

As shown in FIG. 12, in the unit bonding state, the second metal terminal 105B of the second unit 100 is bonded to the first metal terminal 95 of the second electrode pad 55 of the first unit 90. More specifically, the first metal terminal 95 and the second metal terminal 105B are in direct contact with each other in the unit bonding state and are also bonded to each other. As a result, the first metal terminal 95 and the second metal terminal 105B are electrically connected to each other so that the second end portion 22B of the second coil 22 and the second electrode pad 55 are electrically connected to each other.

In the unit bonding state, the first coil 21 and the second coil 22 are arranged to face each other in the Z direction. In one example, the distance DA1 between the first coil 21 and the first element front surface 92A in the Z direction is equal to the distance DB1 between the second coil 22 and the second element front surface 102A in the Z direction. Here, when a difference between the distance DA1 and the distance DB1 is, for example, within 10% of the distance DA1, it can be said that the distance DA1 is equal to the distance DB1. Note that the distances DA1 and DB1 may be changed arbitrarily. In one example, the distance DA1 may be larger than the distance DB1. Further, in one example, the distance DB1 may be larger than the distance DA1.

The shortest distance DC between the first coil 21 and the first metal terminal 95 may be equal to or larger than a distance (DA1+DB1) between the first coil 21 and the second coil 22 in the Z direction. The position of the first metal terminal 95 in the X direction is set such that, for example, the shortest distance DC is equal to or larger than the distance (DA1+DB1) between the first coil 21 and the second coil 22 in the Z direction.

As shown in FIGS. 13 and 14, the first wiring layer 93A of the first connecting portion 93 in the first unit 90 is arranged on the opposite side of the second coil 22 with respect to the first coil 21 in the Z direction. The first wiring layer 103A of the first connecting portion 103 in the second unit 100 is arranged on the opposite side of the first coil 21 with respect to the second coil 22 in the Z direction. Therefore, a distance between the first wiring layer 93A and the first wiring layer 103A in the Z direction is larger than the distance (DA1+DB1) between the first coil 21 and the second coil 22 in the Z direction.

As shown in FIG. 12, the second wiring layer 94A of the second connecting portion 94 in the first unit 90 is arranged at the same position as the first coil 21 in the Z direction. The second wiring layer 104A of the second connecting portion 104 in the second unit 100 is arranged at the same position as the second coil 22 in the Z direction. Therefore, a distance between the second wiring layer 94A and the second wiring layer 104A in the Z direction is equal to the distance (DA1+DB1) between the first coil 21 and the second coil 22 in the Z direction.

As described above, among the first coil 21, the second coil 22, the first connecting portions 93 and 103, and the second connecting portions 94 and 104, which are related to a breakdown voltage, the shortest distances are the distance (DA1+DB1) between the first coil 21 and the second coil 22 and the distance between the second wiring layer 94A and the second wiring layer 104A in the Z direction. In other words, the breakdown voltage of the transformer chip 50 is determined according to the distance (DA1+DB1) between the first coil 21 and the second coil 22 and the distance between the second wiring layer 94A and the second wiring layer 104A in the Z direction.

### [Method of Manufacturing Transformer Chip]

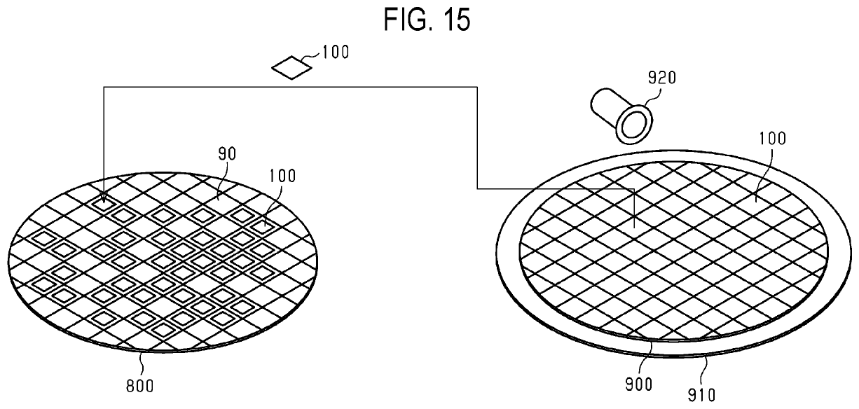

An example of a method of manufacturing the transformer chip 50 will be described with reference to FIG. 15. FIG. 15 schematically shows an example of a process of manufacturing the transformer chip 50.

As shown in FIG. 15, the method of manufacturing the transformer chip 50 includes an operation of preparing a first semiconductor wafer 800 and a second semiconductor wafer 900. The first semiconductor wafer 800 is a wafer on which a plurality of first units 90 are formed. For example, a Si wafer is used as the first semiconductor wafer 800. The second semiconductor wafer 900 is a wafer on which a plurality of second units 100 are formed. For example, a Si wafer is used as the second semiconductor wafer 900.

Further, the method of manufacturing the transformer chip 50 includes an operation of segmenting the second semiconductor wafer 900. In one example, the second semiconductor wafer 900 is cut by a dicing process. More specifically, the second semiconductor wafer 900 is placed on a dicing tape 910. Subsequently, the second semiconductor wafer 900 is cut by a dicing blade 920. As a result, the plurality of second units 100 are manufactured.

Further, the method of manufacturing the transformer chip 50 includes an operation of bonding the plurality of second units 100 to the first semiconductor wafer 800. More specifically, in this operation, the second unit 100 is bonded to a region of the first semiconductor wafer 800 where the first unit 90 is formed. The second unit 100 is arranged such that the second element front surface 102A (see FIG. 12) of the second unit 100 and the first element front surface 92A (see FIG. 12) of the first unit 90 are in direct contact with each other. Then, the second element front surface 102A of the second unit 100 and the first element front surface 92A of the first unit 90 are bonded to each other. At this time, the first metal terminal 95 of the first unit 90 and the second metal terminal 105 of the second unit 100 (both see FIG. 12) are bonded to each other.

Further, the method of manufacturing the transformer chip 50 includes an operation of segmenting the first semiconductor wafer 800. In one example, the first semiconductor wafer 800 is cut by a dicing process. Through the above operations, the transformer chip 50 is manufactured.

### [Actions]

Actions of the first embodiment will be described. A method of manufacturing a plurality of semiconductor chips (the transformer chips 50 in the first embodiment) by forming an element insulating layer on a Si wafer constituting a substrate and then segmenting the Si wafer using a dicing process has been known in the related art. In this method, as the thickness of the element insulating layer on the Si wafer increases, the amount of warp of the Si wafer increases.

On the other hand, in order to improve the dielectric breakdown voltage of a transformer chip, it is necessary to increase a distance between a first coil and a second coil in the Z direction (the distance (DA1+DB1) in the first embodiment). However, since it is difficult to increase the thickness of the element insulating layer due to concerns about an increase in the amount of warpage of the Si wafer, it is not possible to increase the distance between the first coil and the second coil. As a result, it is difficult to improve the dielectric breakdown voltage of the transformer chip.

In this regard, in the first embodiment, the transformer chip 50 has a structure in which the first unit 90 including the first element insulating layer 92 and the second unit 100 including the second element insulating layer 102 are bonded to each other. More specifically, in the first unit 90, the first coil 21 is provided on the first substrate 91 and the first element insulating layer 92 which are formed by the Si wafer (the first semiconductor wafer 800). In the second unit 100, the second coil 22 is provided on the second substrate 101 and the second element insulating layer 102 which are formed by the Si wafer (the second semiconductor wafer 900). Then, since the first element insulating layer 92 and the second element insulating layer 102 are bonded to each other, an element insulating layer between the first coil 21 and the second coil 22 in the Z direction is constructed by pasting together the separately formed first element insulating layer 92 and second element insulating layer 102. Therefore, even if the thickness TA (see FIG. 5) of the first element insulation layer 92 and the thickness TB (see FIG. 8) of the second element insulation layer 102 are not made excessively large, the distance (DA1+DB1) between the first coil 21 and the second coil 22 in the Z direction may be increased. Therefore, it is possible to improve the dielectric breakdown voltage of the transformer chip 50 while suppressing an increase in the amount of warpage of the first semiconductor wafer 800 and the second semiconductor wafer 900.

### Effects

According to the first embodiment, the following effects may be obtained.

(1-1) The transformer chip 50 includes the first unit 90 and the second unit 100 that is bonded to the first unit 90 and is smaller than the first unit 90 in a plan view. The first unit 90 includes the first element insulating layer 92 including the first element front surface 92A facing the second unit 100 and the first element back surface 92B opposite to the first element front surface 92A, the first coil 21 buried in the first element insulating layer 92 at a position spaced apart from the first element front surface 92A in the Z direction, and the first electrode pad 54 that is electrically connected to the first coil 21 and is provided on the first element insulating layer 92 so as to be exposed from the first element front surface 92A. The second unit 100 includes the second element insulating layer 102 including the second element front surface 102A and the second element back surface 102B opposite to the second element front surface 102A, and the second coil 22 buried in the second element insulating layer 102 at a position spaced apart from the second element front surface 102A in the Z direction. In the unit bonding state in which the second unit 100 is bonded to the first unit 90, the first coil 21 and the second coil 22 are arranged to face each other in the Z direction, and the first electrode pad 54 is provided at a different position from the second unit 100 in a plan view.

With this configuration, the element insulating layer between the first coil 21 and the second coil 22 in the Z direction may be formed individually like the first element insulating layer 92 and the second element insulating layer 102. Further, since the first coil 21 and the second coil 22 are provided in the element insulating layer formed by the laminated first element insulating layer 92 and second element insulating layer 102, the distance (DA1+DB1) between the first coil 21 and the second coil 22 in the Z direction may be increased. This makes it possible to improve the dielectric breakdown voltage of the transformer chip 50.

In addition, the first electrode pad 54 is exposed from the first element front surface 92A of the first element insulating layer 92 of the first unit 90. As a result, as compared to a configuration in which the first electrode pad 54 is exposed from the second element front surface 102A of the second element insulating layer 102 of the second unit 100, the length of the conductive path between the first coil 21 and the first electrode pad 54 may be shortened. That is, the length of the conductive path in the Z direction may be shortened. Therefore, a connection wiring between the first electrode pad 54 and the first coil 21 may be easily formed.

(1-2) The first unit 90 includes the second electrode pad 55 that is electrically connected to the second coil 22 in the unit bonding state. In the unit bonding state, the second electrode pad 55 is provided at a different position from the second unit 100 in the first element insulating layer 92 in a plan view.

With this configuration, since the second electrode pad 55 is provided on the first element insulating layer 92, as compared to a configuration in which the second electrode pad 55 is exposed from the second element front surface 102A of the second element insulating layer 102 of the second unit 100, the second electrode pad 55 may be easily formed.

(1-3) The first unit 90 includes the first metal terminal 95 provided on the first element insulating layer 92 so as to be exposed from the first element front surface 92A. The second unit 100 includes the second metal terminal 105 provided on the second element insulating layer 102 so as to be exposed from the second element front surface 102A. The first unit 90 and the second unit 100 are in the unit bonding state when the first element front surface 92A and the second element front surface 102A are bonded to each other and the first metal terminal 95 and the second metal terminal 105 are bonded to each other.

With this configuration, the first element front surface 92A and the second element front surface 102A are bonded to each other and the first metal terminal 95 and the second metal terminal 105 are bonded to each other, so that the first unit 90 and the second unit 100 may be directly bonded to each other. Therefore, a bonding material for bonding the first unit 90 and the second unit 100 may be omitted.

(1-4) Both the first metal terminal 95 and the second metal terminal 105 are arranged outward from both the first coil 21 and the second coil 22 in a plan view. With this configuration, it is possible to suppress the first metal terminal 95 and the second metal terminal 105 from influencing a magnetic field formed by the first coil 21 and the second coil 22.

(1-5) In a plan view, the first electrode pad 54 and the second electrode pad 55 are arranged in a distributed manner on both sides of the first coil 21 in the X direction. In a plan view, the first metal terminal 95 is arranged between the second electrode pad 55 and the first coil 21 in the X direction.

With this configuration, a shape such as a recess or an opening for exposing the second electrode pad 55 in the second unit 100 is not necessary. Therefore, even if the second unit 100 has a simple shape such as a rectangular plate shape, the second electrode pad 55 may be exposed from the first element front surface 92A in the unit bonding state.

(1-6) The first metal terminal 95 is electrically connected to the second electrode pad 55. The second metal terminal 105 is electrically connected to the second coil 22. By bonding the first metal terminal 95 and the second metal terminal 105, the second coil 22 and the second electrode pad 55 are electrically connected to each other.

With this configuration, in the unit bonding state, the second coil 22 and the second electrode pad 55 are electrically connected to each other via the first metal terminal 95 and the second metal terminal 105. In this way, the second electrode pad 55 provided on the first element insulating layer 92 of the first unit 90 and the second coil 22 of the second unit 100 may easily be electrically connected to each other in the unit bonding state.

(1-7) The first coil 21 is arranged to be closer to the first element back surface 92B than the first element front surface 92A of the first element insulating layer 92 in the Z direction. With this configuration, the distance between the first coil 21 and the second coil 22 in the Z direction may be increased. This makes it possible to improve the dielectric breakdown voltage of the transformer chip 50.

(1-8) The second coil 22 is arranged to be closer to the second element back surface 102B than the second element front surface 102A of the second element insulating layer 102 in the Z direction. With this configuration, the distance between the first coil 21 and the second coil 22 in the Z direction may be increased. This makes it possible to improve the dielectric breakdown voltage of the transformer chip 50.

(1-9) The first unit 90 includes the first wiring layer 93A that is provided inside the first element insulating layer 92 and is electrically connected to the first coil 21, and the first connection wiring 93B that is provided inside the first element insulating layer 92 and electrically connects the first wiring layer 93A and the first electrode pad 54.

With this configuration, the first coil 21 and the first electrode pad 54 may be electrically connected to each other within the first unit 90 (within the first element insulating layer 92). Therefore, as compared to a configuration in which the first coil 21 and the first electrode pad 54 are electrically connected to each other outside the first unit 90, the length of the conductive path between the first coil 21 and the first electrode pad 54 may be shortened.

(1-10) The second unit 100 includes the first wiring layer 103A that is provided inside the second element insulating layer 102 and is electrically connected to the second coil 22, and the first connection wiring 103B that is provided inside the second element insulating layer 102, is electrically connected to the first wiring layer 103A, and is exposed from the second element front surface 102A of the second element insulating layer 102. In the unit bonding state, the first connection wiring 103B is electrically connected to the second electrode pad 55.

With this configuration, the second coil 22 and the second electrode pad 55 may be electrically connected to each other within the transformer chip 50. Therefore, as compared to a configuration in which the second coil 22 and the second electrode pad 55 are electrically connected to each other outside the transformer chip 50, the length of a conductive path between the second coil 22 and the second electrode pad 55 may be shortened.

### Second Embodiment

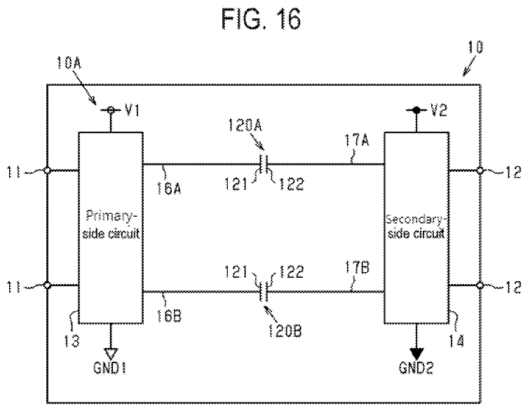

A signal transmission device 10 according to a second embodiment will be described with reference to FIGS. 16 to 18. The signal transmission device 10 according to the second embodiment is different from the signal transmission device 10 according to the first embodiment in that a capacitor chip 130 is used instead of the transformer chip 50. In the following description, the same constituent elements as those in the first embodiment are denoted by the same reference numerals, and thus descriptions thereof will be omitted.

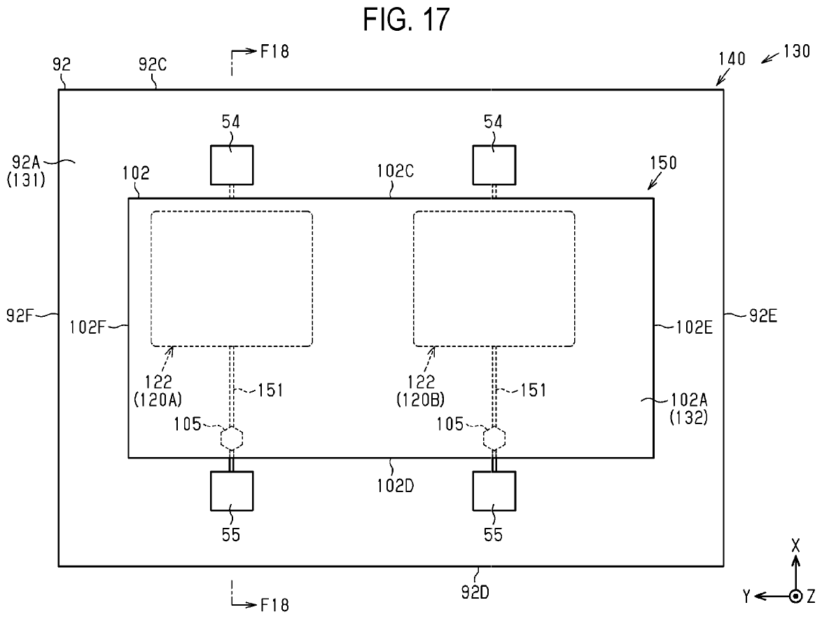

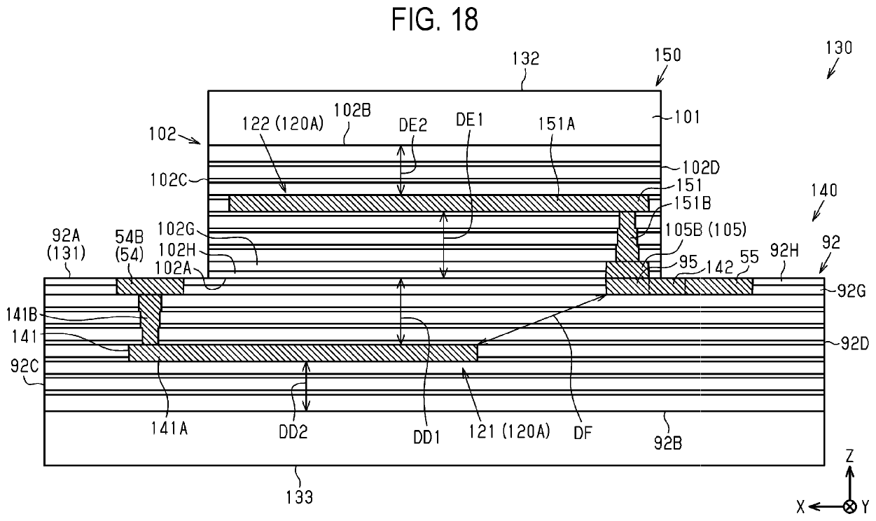

FIG. 16 shows a simplified example of a circuit configuration of the signal transmission device 10 of the first embodiment. FIG. 17 schematically shows a planar structure of the capacitor chip 130. FIG. 18 shows a cross-sectional structure of the capacitor chip 130 taken along line F18-F18 in FIG. 17, mainly showing a cross-sectional structure of a capacitor 120A which will be described later.

As shown in FIG. 16, the signal transmission device 10 includes capacitors 120A and 120B instead of the transformers 15A and 15B. The capacitor 120A transmits a set signal from the primary-side circuit 13 to the secondary-side circuit 14 while electrically insulating the primary-side circuit 13 and the secondary-side circuit 14. The capacitor 120A has a first electrode plate 121 and a second electrode plate 122 that constitute electrodes of the capacitor 120A. The first electrode plate 121 of the capacitor 120A is electrically connected to the primary-side signal line 16A, and the second electrode plate 122 is electrically connected to the secondary-side signal line 17A.

The capacitor 120B transmits a reset signal from the primary-side circuit 13 to the secondary-side circuit 14 while electrically insulating the primary-side circuit 13 and the secondary-side circuit 14. The capacitor 120B has a first electrode plate 121 and a second electrode plate 122. The first electrode plate 121 of the capacitor 120B is electrically connected to the primary-side signal line 16B, and the second electrode plate 122 of the capacitor 120B is electrically connected to the secondary-side signal line 17B. Here, in the second embodiment, the first electrode plate 121 of each of the capacitors 120A and 120B corresponds to a “first insulating element,” and the second electrode plate 122 of each of the capacitors 120A and 120B corresponds to a “second insulating element.”

The dielectric breakdown voltage of the signal transmission device 10 is, for example, 2,500 Vrms or more and 7,500 Vrms or less. The dielectric breakdown voltage of the signal transmission device 10 of the second embodiment is about 5,000 Vrms, similar to the first embodiment. However, a specific numerical value of the dielectric breakdown voltage of the signal transmission device 10 is not limited thereto and may be changed arbitrarily.

As shown in FIGS. 17 and 18, the signal transmission device 10 of the second embodiment includes the capacitor chip 130 instead of the transformer chip 50 (see FIG. 2). Further, since the capacitor 120B has the same configuration as the capacitor 120A, a detailed description thereof will be omitted. Here, in the second embodiment, the capacitor chip 130 is an example of an “insulation chip.”

The capacitor chip 130 has a configuration in which the transformers 15A and 15B of the transformer chip 50 are replaced with the capacitors 120A and 120B. Therefore, in the capacitor chip 130, the same constituent elements as those in the transformer chip 50 are denoted by the same reference numerals as those in the transformer chip 50, and descriptions thereof will be omitted.

Similarly to the transformer chip 50, the capacitor chip 130 is formed in a convex shape when viewed from the Y direction. The capacitor chip 130 has a first chip front surface 131, a second chip front surface 132, and a chip back surface 133 facing the opposite side of these chip front surfaces 131 and 132. Although not shown, the chip back surface 133 of the capacitor chip 130 is bonded to the first die pad 61 (see FIG. 3) by a conductive bonding material SD. The second chip front surface 132 is located on the opposite side of the first die pad 61 with respect to the first chip front surface 131 in the Z direction. In other words, the first chip front surface 131 is located to be closer to the first die pad 61 than the second chip front surface 132 in the Z direction.

As shown in FIGS. 17 and 18, a plurality of first electrode pads 54 and a plurality of second electrode pads 55 are formed on the first chip front surface 131 of the capacitor chip 130. The plurality of first electrode pads 54 are arranged at an end closer to the first chip 30 (see FIG. 3) of both ends of the first chip front surface 131 in the X direction. The plurality of first electrode pads 54 are arranged to be spaced apart from each other in the Y direction. The plurality of second electrode pads 55 are formed at an end closer to the second chip 40 (see FIG. 3) of both ends of the first chip front surface 131 in the X direction. The plurality of second electrode pads 55 are arranged to be spaced apart from each other in the Y direction.

The capacitor chip 130 includes a first unit 140 and a second unit 150 bonded to the first unit 140. The first unit 140 is formed in a rectangular flat plate shape whose thickness direction is the Z direction. In a plan view, the first unit 140 is formed in a rectangular shape in which the X direction is the lateral direction and the Y direction is the longitudinal direction.

The first unit 140 includes a first electrode pad 54, a second electrode pad 55, a first substrate 91, a first element insulating layer 92, a first electrode plate 121 of each of the capacitors 120A and 120B, a first connecting portion 141, a first metal terminal 95, and a second connecting portion 142.

As shown in FIG. 17, the first electrode pad 54 is arranged to be closer to the first element side-surface 92C of the first element insulating layer 92 than the second unit 150 in a plan view. The second electrode pad 55 is arranged to be closer to the first element side-surface 92D of the first element insulating layer 92 than the second unit 150 in a plan view. The numbers of first electrode pads 54 and second electrode pads 55 are set according to the number of capacitors 120A and 120B. Specifically, the numbers of first electrode pads 54 and second electrode pads 55 are the same as the number of capacitors 120A and 120B. In the second embodiment, since the total number of capacitors 120A and 120B is two, the number of first electrode pads 54 and the number of second electrode pads 55 are each two.

The two first electrode pads 54 are arranged at the same position in the X direction and spaced apart from each other in the Y direction. In the Y direction, each first electrode pad 54 is arranged at the same position as the first electrode plate 121 of each of the capacitors 120A and 120B. The two second electrode pads 55 are arranged at the same position in the X direction and spaced apart from each other in the Y direction. In the Y direction, each second electrode pad 55 is arranged at the same position as the first electrode plate 121 (the second electrode plate 122) of each of the capacitors 120A and 120B.

The first electrode plate 121 of each of the capacitors 120A and 120B is an electrode plate formed in a flat plate shape in which the Z direction is the thickness direction. A shape of the first electrode plate 121 in a plan view is, for example, rectangular. These first electrode plates 121 are arranged at the same position in the X direction and spaced apart from each other in the Y direction.

As shown in FIG. 18, the first electrode plate 121 is buried in the first element insulating layer 92. More specifically, the first electrode plate 121 is arranged at a position spaced apart from the first element front surface 92A of the first element insulating layer 92 in the Z direction. The first electrode plate 121 is arranged at a position spaced apart from the first element back surface 92B of the first element insulating layer 92 in the Z direction. Therefore, the first electrode plate 121 is not exposed from the first element insulating layer 92. In this way, the first electrode plate 121 is buried in the first element insulating layer 92. The first electrode plate 121 is made of a material containing one or more appropriately selected from the group consisting of, for example, Ti, TiN, Au, Ag, Cu, Al, and W. In one example, the first electrode plate 121 is formed of a material containing Cu. The shape of the first electrode plate 121 in a plan view may be changed arbitrarily.

The first electrode plate 121 is arranged to be closer to the first element back surface 92B than the first element front surface 92A of the first element insulating layer 92 in the Z direction. That is, a distance DD1 between the first electrode plate 121 and the first element front surface 92A in the Z direction is larger than a distance DD2 between the first electrode plate 121 and the first element back surface 92B in the Z direction. In one example, the distance DD1 may be three times or less than the distance DD2. In one example, the distance DD1 may be twice or less than the distance DD2. The distances DD1 and DD2 may be changed arbitrarily. In one example, the distance DD1 may be larger than twice the distance DD2.

The first connecting portion 141 connects the first electrode pad 54 and the first electrode plate 121. The first connecting portion 141 includes a wiring layer 141A extending in the X direction and a via 141B extending in the Z direction.

The wiring layer 141A is connected to the first electrode plate 121. The wiring layer 141A is arranged at the same position as the first electrode plate 121 in the Z direction. The wiring layer 141A includes a portion that overlaps the first electrode pad 54 in a plan view. The via 141B is connected to this portion. The via 141B connects the wiring layer 141A and the first electrode pad 54. As a result, the first electrode pad 54 and the first electrode plate 121 are electrically connected to each other. The wiring layer 141A and the via 141B are made of a material containing one or more appropriately selected from the group consisting of, for example, Ti, TiN, Au, Ag, Cu, Al, and W.

The second connecting portion 142 connects the first metal terminal 95 and the second electrode pad 55. The second connecting portion 142 is a wiring layer extending in the X direction in a plan view. The second connecting portion 142 is arranged at the same position as the first metal terminal 95 and the second electrode pad 55 in the Z direction. The second connecting portion 142 may be formed of the same material as, for example, the first metal terminal 95 and the second electrode pad 55. In this case, the first metal terminal 95, the second connecting portion 142, and the second electrode pad 55 are integrated.

The second unit 150 is formed in a rectangular flat plate shape whose thickness direction is the Z direction. In a plan view, the second unit 150 is formed in a rectangular shape in which the X direction is the lateral direction and the Y direction is the longitudinal direction.

The second unit 150 includes a second substrate 101, a second element insulating layer 102, a second electrode plate 122 of each of the capacitors 120A and 120B, a second metal terminal 105, and a connecting portion 151. As shown in FIG. 17, the second electrode plate 122 of each of the capacitors 120A and 120B is an electrode plate formed in a flat plate shape in which the Z direction is the thickness direction. A shape of the second electrode plate 122 in a plan view is, for example, rectangular. A size of the second electrode plate 122 is the same as that of the first electrode plate 121. That is, dimensions of the second electrode plate 122 in the X, Y, and Z directions are equal to those of the first electrode plate 121 in the X, Y, and Z directions. These second electrode plates 122 are arranged at the same position in the X direction and spaced apart from each other in the Y direction. FIG. 18 shows the second electrode plate 122 of the capacitor 120A and does not show the second electrode plate 122 of the capacitor 120B.

As shown in FIG. 18, the second electrode plate 122 is buried in the second element insulating layer 102. More specifically, the second electrode plate 122 is arranged at a position spaced apart from the second element front surface 102A of the second element insulating layer 102 in the Z direction. The second electrode plate 122 is arranged at a position spaced apart from the second element back surface 102B of the second element insulating layer 102 in the Z direction. Therefore, the second electrode plate 122 is not exposed from the second element insulating layer 102. In this way, the second electrode plate 122 is buried in the second element insulating layer 102. The second electrode plate 122 is made of a material containing one or more appropriately selected from the group consisting of, for example, Ti, TiN, Au, Ag, Cu, Al, and W. In one example, the second electrode plate 122 is formed of a material containing Cu. The shape of the second electrode plate 122 in a plan view may be changed arbitrarily.

The second electrode plate 122 is arranged to be closer to the second element back surface 102B than the second element front surface 102A of the second element insulating layer 102 in the Z direction. That is, a distance DE1 between the second electrode plate 122 and the second element front surface 102A in the Z direction is larger than a distance DE2 between the second electrode plate 122 and the second element back surface 102B in the Z direction. In one example, the distance DE1 may be three times or less than the distance DE2. In one example, the distance DE1 may be twice or less than the distance DE2. The distances DE1 and DE2 may be changed arbitrarily. In one example, the distance DE1 may be larger than twice the distance DE2.

The connecting portion 151 connects the second electrode pad 55 and the second electrode plate 122. The connecting portion 151 includes a wiring layer 151A extending in the X direction and a via 151B extending in the Z direction. The wiring layer 151A is connected to the second electrode plate 122. The wiring layer 151A is arranged at the same position as the second electrode plate 122 in the Z direction. The wiring layer 151A includes a portion that overlaps the second electrode pad 55 in a plan view. The via 151B is connected to this portion. The via 151B connects the wiring layer 151A and the second electrode pad 55. As a result, the second electrode pad 55 and the second electrode plate 122 are electrically connected to each other. The wiring layer 151A and the via 151B are made of a material containing one or more appropriately selected from the group consisting of, for example, Ti, TiN, Au, Ag, Cu, Al, and W.

In the second unit 150, the second element side-surface 102D is arranged to be closer to the first element side-surface 92D of the first unit 140 in the X direction, and the second element side-surface 102C is arranged to be closer to the first element side-surface 92C of the first unit 140. Therefore, the second metal terminal 105 of the second unit 150 is arranged to face the first metal terminal 95 of the first unit 140 in the Z direction.

In a state where the second unit 150 is bonded to the first unit 140 (hereinafter referred to as a “unit bonding state”), the second element front surface 102A of the second element insulating layer 102 is in contact with the first element front surface 92A of the first element insulating layer 92. In one example, the second element front surface 102A is in contact with the first element front surface 92A over its entire surface.

As shown in FIGS. 17 and 18, the second unit 150 is smaller than the first unit 140. More specifically, in a plan view, a dimension in the X direction of the second unit 150 is smaller than that in the X direction of the first unit 140, and a dimension in the Y direction of the second unit 150 is smaller than that in the Y direction of the first unit 140. Further, in a plan view, the second unit 150 is arranged at the center of the first unit 140 in the X direction and the Y direction. Therefore, the first element front surface 92A of the first element insulating layer 92 includes a rectangular frame-shaped exposure region surrounding the second unit 150 in a plan view. This exposure region constitutes the first chip front surface 131 of the capacitor chip 130.

As shown in FIG. 17, the first electrode pad 54 and the second electrode pad 55 are provided at different positions from the second unit 150 in a plan view. More specifically, in a plan view, the first electrode pad 54 is arranged to be closer to the first element side-surface 92C than the second unit 150. In a plan view, the second electrode pad 55 is arranged to be closer to the first element side-surface 92D than the second unit 150.

As shown in FIG. 18, in the unit bonding state, the second metal terminal 105 of the second unit 150 is bonded to the first metal terminal 95 of the second electrode pad 55 of the first unit 140. More specifically, the first metal terminal 95 and the second metal terminal 105 are in direct contact with each other in the unit bonding state and are also bonded to each other. As a result, the first metal terminal 95 and the second metal terminal 105 are electrically connected to each other, so that the second electrode plate 122 and the second electrode pad 55 are electrically connected to each other.

In the unit bonding state, the first electrode plate 121 and the second electrode plate 122 are arranged to face each other in the Z direction. In one example, the distance DD1 between the first electrode plate 121 and the first element front surface 92A in the Z direction is equal to the distance DE1 between the second electrode plate 122 and the second element front surface 102A in the Z direction. Here, when a difference between the distance DD1 and the distance DE1 is, for example, within 10% of the distance DD1, it can be said that the distance DD1 is equal to the distance DE1. The distances DD1 and DE1 may be changed arbitrarily. In one example, the distance DD1 may be larger than the distance DE1. Further, in one example, the distance DE1 may be larger than the distance DD1.

The shortest distance DF between the first electrode plate 121 and the first metal terminal 95 may be equal to or larger than a distance (DD1+DE1) between the first electrode plate 121 and the second electrode plate 122 in the Z direction. A position of the first metal terminal 95 in the X direction is set such that, for example, the shortest distance DF is equal to or larger than the distance (DD1+DE1) between the first electrode plate 121 and the second electrode plate 122 in the Z direction.

The wiring layer 141A of the first connecting portion 141 in the first unit 140 is arranged at the same position as the first electrode plate 121 in the Z direction. The wiring layer 151A of the connecting portion 151 in the second unit 150 is arranged at the same position as the second electrode plate 122 in the Z direction. Therefore, a distance between the wiring layer 141A and the wiring layer 151A in the Z direction is equal to the distance (DD1+DE1) between the first electrode plate 121 and the second electrode plate 122 in the Z direction.

As described above, among the first electrode plate 121, the second electrode plate 122, the first connecting portion 141, and the connecting portion 151, which are related to a breakdown voltage, the shortest distances are the distance (DD1+DE1) between the first electrode plate 121 and the second electrode plate 122 and the distance between the wiring layer 141A and the wiring layer 151A in the Z direction. That is, the breakdown voltage of the capacitor chip 130 is determined according to the distance (DD1+DE1) between the first electrode plate 121 and the second electrode plate 122 and the distance between the wiring layer 141A and the wiring layer 151A in the Z direction. According to the second embodiment, the same effects as the first embodiment may be obtained.

### Modifications

Each of the above-described embodiments may be modified as follows, for example. Each of the above-described embodiments and each of the following modifications may be combined with each other to the extent that they are not technically contradictory. Further, in the following modifications, parts common to those in the above-described embodiments are denoted by the same reference numerals as in the above-described embodiments, and descriptions thereof will be omitted.

### [Modifications of Insulation Chip]

In the first embodiment, the first coil 21 may be arranged to be closer to the first element front surface 92A than the first element back surface 92B of the first element insulating layer 92 in the Z direction. Further, the first coil 21 may be arranged at the center of the first element insulating layer 92 in the Z direction.

In the first embodiment, the second coil 22 may be arranged to be closer to the second element front surface 102A than the second element back surface 102B of the second element insulating layer 102 in the Z direction. Further, the second coil 22 may be arranged at the center of the second element insulating layer 102 in the Z direction.

In the first embodiment, the first coil 21 and the first electrode pad 54 may be electrically connected to each other outside the transformer chip 50.

In the first embodiment, the size of the second unit 100 may be changed arbitrarily. In one example, the dimension of the second unit 100 in the Y direction may be equal to the dimension of the first unit 90 in the Y direction.

In the second embodiment, the first electrode plate 121 may be arranged to be closer to the first element front surface 92A than the first element back surface 92B of the first element insulating layer 92 in the Z direction. Further, the first electrode plate 121 may be arranged at the center of the first element insulating layer 92 in the Z direction.

In the second embodiment, the second electrode plate 122 may be arranged to be closer to the second element front surface 102A than the second element back surface 102B of the second element insulating layer 102 in the Z direction. Further, the second electrode plate 122 may be arranged at the center of the second element insulating layer 102 in the Z direction.

In the second embodiment, the first electrode plate 121 and the first electrode pad 54 may be electrically connected to each other outside the capacitor chip 130.

In the second embodiment, the size of the second unit 150 may be changed arbitrarily. In one example, the dimension of the second unit 150 in the Y direction may be equal to the dimension of the first unit 140 in the Y direction.

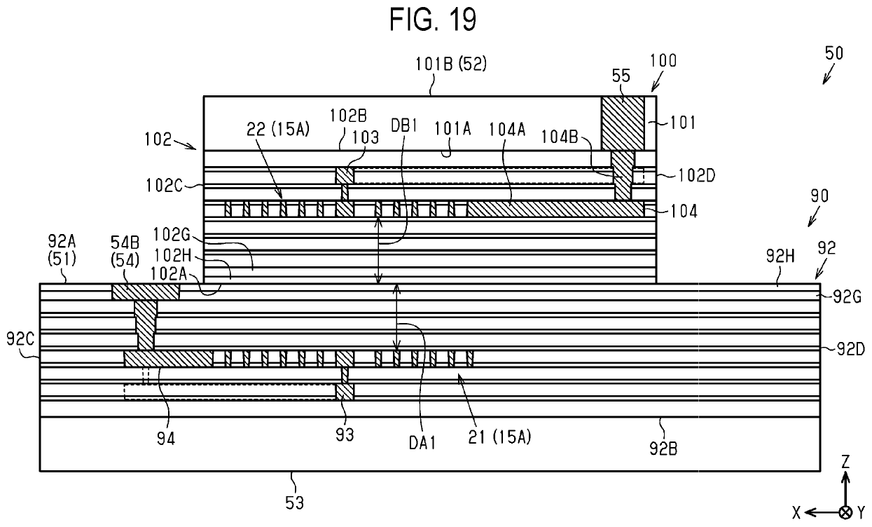

In each embodiment, as shown in FIG. 19, the second electrode pad 55 may be provided in the second unit 100. The second electrode pad 55 is exposed from the second chip front surface 52 of the transformer chip 50. In one example, the second electrode pad 55 penetrates the second substrate 101 in the Z direction. More specifically, the second substrate 101 has a second substrate front surface 101A and a second substrate back surface 101B opposite to the second substrate front surface 101A. The second substrate 101 is provided such that the second substrate front surface 101A is in contact with the second element back surface 102B of the second element insulating layer 102. The second substrate back surface 101B constitutes the second chip front surface 52. The second electrode pad 55 is exposed from the second substrate back surface 101B. The second electrode pad 55 is formed, for example, as a through-silicon via (TSV).

In the second connecting portion 104, the second connection wiring 104B is provided to be closer to the second substrate 101 than the second wiring layer 104A in the Z direction. Although not shown, in the first connecting portion 103, the first connection wiring 103B is provided to be closer to the second substrate 101 than the first wiring layer 103A in the Z direction.

In this case, the first unit 90 and the second unit 100 are bonded to each other by bonding the first element front surface 92A of the first element insulating layer 92 and the second element front surface 102A of the second element insulating layer 102.

In each embodiment, the first unit 90 (140) and the second unit 100 (150) are directly bonded to each other, but a method of boding the first unit 90 (140) and the second unit 100 (150) is not limited thereto.

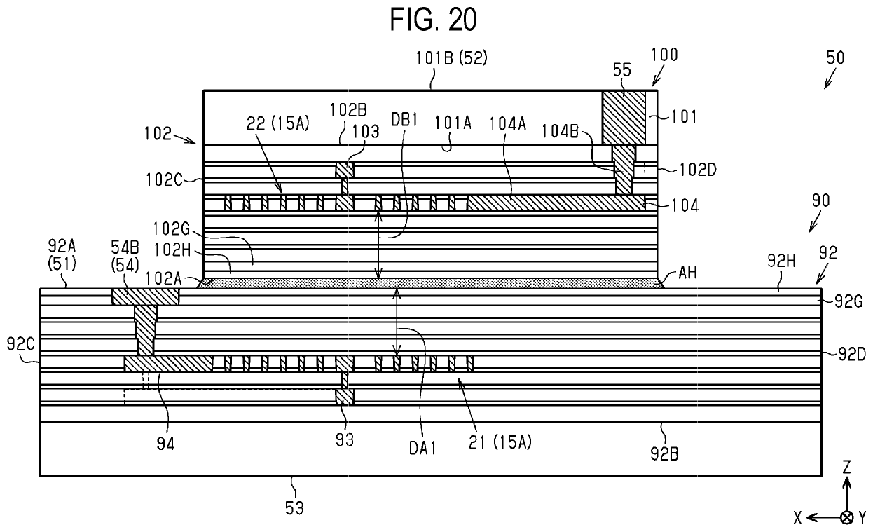

For example, as shown in FIG. 20, the first unit 90 and the second unit 100 may be bonded to each other by an insulating bonding material AH. More specifically, the insulating bonding material AH is interposed between the first unit 90 and the second unit 100 in the Z direction. Therefore, the insulating bonding material AH bonds the first element insulating layer 92 of the first unit 90 and the second element insulating layer 102 of the second unit 100. The insulating bonding material AH is formed of, for example, a material containing epoxy resin.

In each embodiment, at least one of the protective layer 92G and the passivation layer 92H may be omitted from the first element insulating layer 92. When both the protective layer 92G and the passivation layer 92H are omitted from the first element insulating layer 92, the first element front surface 92A of the first element insulating layer 92 is constituted by the second insulating film 92Q. Therefore, in the unit bonding state, the second insulating film 92Q is bonded to the second element front surface 102A of the second element insulating layer 102 of the second unit 100.

In each embodiment, at least one of the protective layer 102G and the passivation layer 102H may be omitted from the second element insulating layer 102. When both the protective layer 102G and the passivation layer 102H are omitted from the second element insulating layer 102, the second element front surface 102A of the second element insulating layer 102 is constituted by the second insulating film 102Q. Therefore, in the unit bonding state, the second insulating film 102Q is bonded to the first element front surface 92A of the first element insulating layer 92 of the first unit 90. Here, when both the protective layer 92G and the passivation layer 92H are omitted from the first element insulating layer 92 of the first unit 90, the second insulating film 102Q of the second element insulating layer 102 and the second insulating film 92Q of the first element insulating layer 92 are bonded to each other in the unit bonding state.

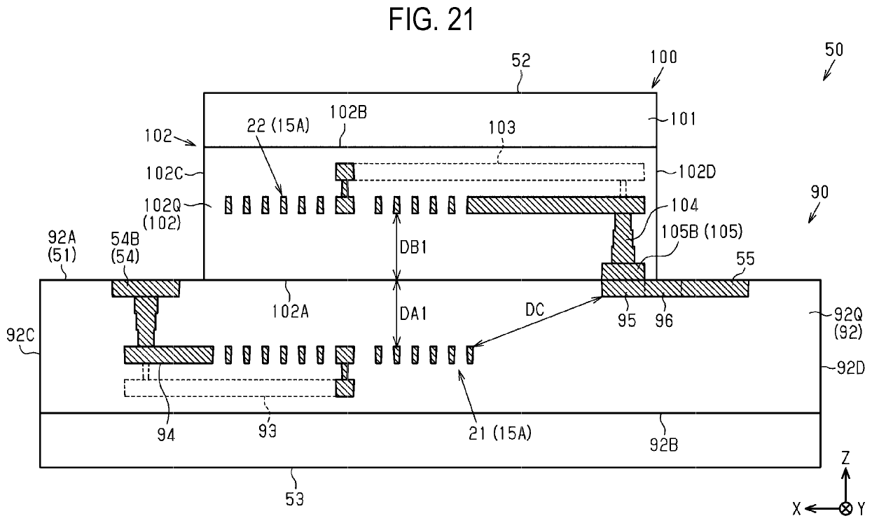

In each embodiment, the configuration of the first element insulating layer 92 may be changed arbitrarily. In one example, as shown in FIG. 21, the first element insulating layer 92 may be formed of a laminate of a plurality of second insulating films 92Q. That is, the first insulating film 92P may be omitted from the first element insulating layer 92. In the example shown in FIG. 21, the protective layer 92G and the passivation layer 92H are also omitted. Therefore, the first element insulating layer 92 is formed of the first insulating film 92P.

In each embodiment, the configuration of the second element insulating layer 102 may be changed arbitrarily. In one example, as shown in FIG. 21, the second element insulating layer 102 may be formed of a laminate of a plurality of second insulating films 102Q. That is, the first insulating film 102P may be omitted from the second element insulating layer 102. In the example shown in FIG. 21, the protective layer 102G and the passivation layer 92H are also omitted.

### [Modifications of Signal Transmission Device]

In the first embodiment, the arrangement configuration of the transformer chip 50 may be changed arbitrarily. In one example, the transformer chip 50 may be arranged on the second die pad 71. In this case, both the transformer chip 50 and the second chip 40 are arranged on the second die pad 71.

In the second embodiment, the arrangement configuration of the capacitor chip 130 may be changed arbitrarily. In one example, the capacitor chip 130 may be arranged on the second die pad 71. In this case, both the capacitor chip 130 and the second chip 40 are arranged on the second die pad 71.

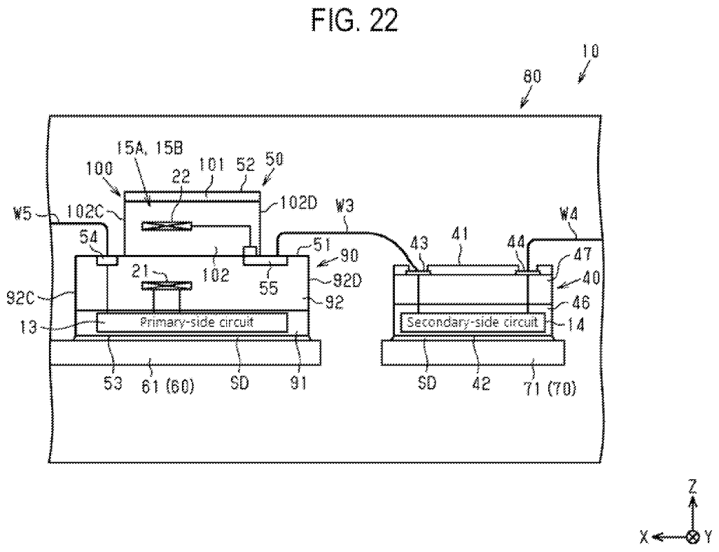

In the first embodiment, as shown in FIG. 22, the transformer chip 50 may include the primary-side circuit 13. The primary-side circuit 13 is provided in the first unit 90. More specifically, the primary-side circuit 13 is provided, for example, on the first substrate 91 which is a semiconductor substrate. The first coil 21 and the primary-side circuit 13 are electrically connected to each other within the transformer chip 50. More specifically, the first coil 21 and the primary-side circuit 13 are electrically connected to each other within the first unit 90. The wiring layer that electrically connects the first coil 21 and the primary-side circuit 13 is provided, for example, in the first element insulating layer 92. In this case, a plurality of first electrode pads 54 are individually electrically connected to a plurality of first leads 62 (see FIG. 2) of the first lead frame 60 by a plurality of wires W5.

The configuration of the capacitor chip 130 of the second embodiment may be similarly changed to include the primary-side circuit 13. The first electrode plate 121 and the primary-side circuit 13 are electrically connected to each other within the capacitor chip 130. The wiring layer that electrically connects the first electrode plate 121 and the primary-side circuit 13 is provided, for example, in the first element insulating layer 92.

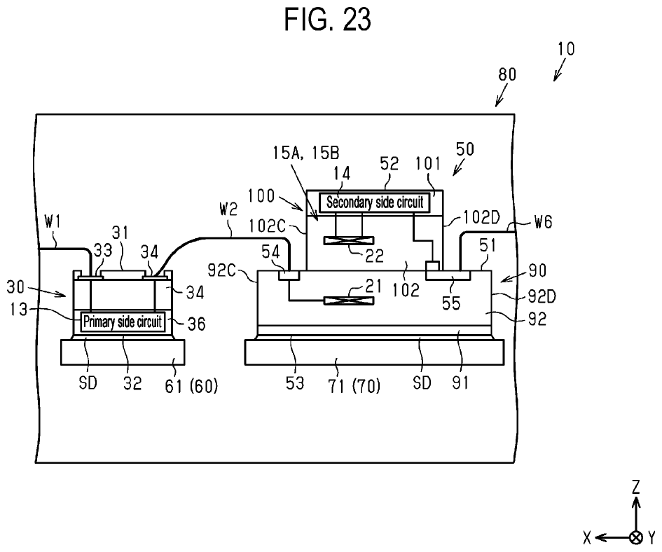

In the first embodiment, as shown in FIG. 23, the transformer chip 50 may include the secondary-side circuit 14. The secondary-side circuit 14 is provided in the second unit 100. More specifically, the secondary-side circuit 14 is provided, for example, on the second substrate 101 which is a semiconductor substrate. The second coil 22 and the secondary-side circuit 14 are electrically connected to each other within the transformer chip 50. More specifically, the second coil 22 and the secondary-side circuit 14 are electrically connected to each other within the second unit 100. The wiring layer that electrically connects the second coil 22 and the secondary-side circuit 14 is provided, for example, in the second element insulating layer 102. In this case, a plurality of second electrode pads 55 are electrically connected individually to a plurality of second leads 72 (see FIG. 2) of the second lead frame 70 by a plurality of wires W6. In this case, the transformer chip 50 is arranged, for example, on the second die pad 71 of the second lead frame 70.

The configuration of the capacitor chip 130 of the second embodiment may be similarly changed to include the secondary-side circuit 14. The second electrode plate 122 and the secondary-side circuit 14 are electrically connected to each other within the capacitor chip 130. The wiring layer that electrically connects the second electrode plate 122 and the secondary-side circuit 14 is provided, for example, in the second element insulating layer 102. In this case, the capacitor chip 130 is arranged, for example, on the second die pad 71.

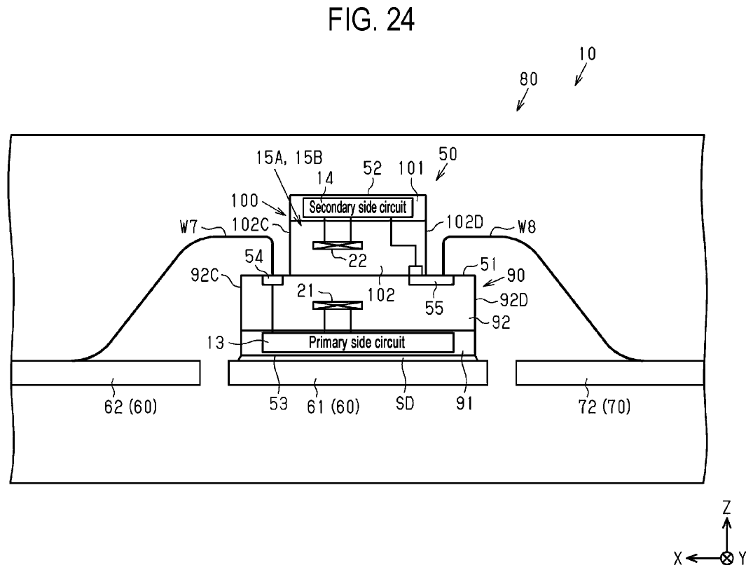

In the first embodiment, as shown in FIG. 24, the transformer chip 50 may include both the primary-side circuit 13 and the secondary-side circuit 14. The primary-side circuit 13 is provided in the first unit 90, and the secondary-side circuit 14 is provided in the second unit 100. More specifically, the primary-side circuit 13 is provided, for example, on the first substrate 91 which is a semiconductor substrate, and the secondary-side circuit 14 is provided, for example, on the second substrate 101 which is a semiconductor substrate. The first coil 21 and the primary-side circuit 13 are electrically connected to each other within the transformer chip 50, and the second coil 22 and the secondary-side circuit 14 are electrically connected to each other within the transformer chip 50. More specifically, the first coil 21 and the primary-side circuit 13 are electrically connected to each other within the first unit 90. The second coil 22 and the secondary-side circuit 14 are electrically connected to each other within the second unit 100. The wiring layer that electrically connects the first coil 21 and the primary-side circuit 13 is provided, for example, in the first element insulating layer 92. The wiring layer that electrically connects the second coil 22 and the secondary-side circuit 14 is provided, for example, in the second element insulating layer 102. The transformer chip 50 is arranged on the first die pad 61 of the first lead frame 60. The transformer chip 50 may be arranged on the second die pad 71 of the second lead frame 70.

A plurality of first electrode pads 54 are electrically connected individually to a plurality of first leads 62 of the first lead frame 60 by a plurality of wires W7. A plurality of second electrode pads 55 are electrically connected individually to a plurality of second leads 72 of the second lead frame 70 by a plurality of wires W8.

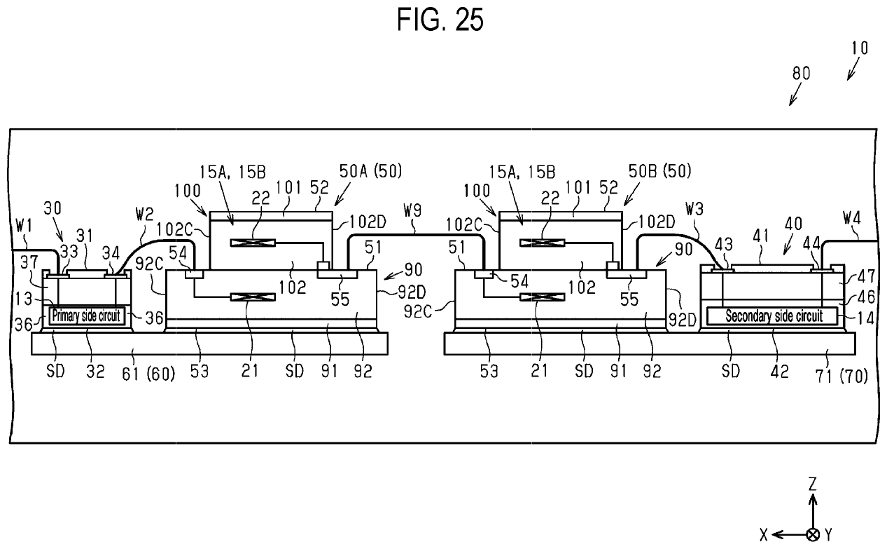

In each embodiment, the signal transmission device 10 may include, for example, a plurality of insulation chips. In one example, as shown in FIG. 25, the signal transmission device 10 may include two transformer chips 50. Here, for the sake of convenience in description, the two transformer chips 50 are referred to as a “first transformer chip 50A” and a “second transformer chip 50B.” The first transformer chip 50A is arranged on the first die pad 61 of the first lead frame 60. The second transformer chip 50B is arranged on the second die pad 71 of the second lead frame 70. In this way, both the first transformer chip 50A and the first chip 30 are arranged on the first die pad 61, and both the second transformer chip 50B and the second chip 40 are arranged on the second die pad 71. Here, the first transformer chip 50A is an example of a “first insulation chip,” and the second transformer chip 50B is an example of a “second insulation chip.”

The first transformer chip 50A is arranged to be closer to the second chip 40 than the first chip 30. The second transformer chip 50B is arranged to be closer to the first chip 30 than the second chip 40. Therefore, the first chip 30, the first transformer chip 50A, the second transformer chip 50B, and the second chip 40 are arranged in this order from the first lead 62 of the first lead frame 60 toward the second lead 72 of the second lead frame 70.

The first chip 30 and the first transformer chip 50A are electrically connected to each other by a plurality of wires W1. The second chip 40 and the second transformer chip 50B are electrically connected to each other by a plurality of wires W3. A manner in which the first chip 30 and the first transformer chip 50A are connected to each other by the plurality of wires W1 is the same as that in which the first chip 30 and the transformer chip 50 are connected to each other by the plurality of wires W1 in the first embodiment. A manner in which the second chip 40 and the second transformer chip 50B are connected to each other by a plurality of wires W2 is the same as that in which the second chip 40 and the transformer chip 50 are connected to each other by the plurality of wires W2 in the first embodiment.

The first transformer chip 50A and the second transformer chip 50B are electrically connected to each other by a plurality of wires W9. More specifically, a plurality of second electrode pads 55 of the first transformer chip 50A are individually connected to a plurality of first electrode pads 54 of the second transformer chip 50B by the plurality of wires W9. As a result, the second coil 22 of the first transformer chip 50A and the first coil 21 of the second transformer chip 50B are electrically connected to each other.

With this configuration, since the first chip 30 and the second chip 40 are insulated from each other by a double insulation structure of the first transformer chip 50A and the second transformer chip 50B, as compared to a configuration in which the first chip 30 and the second chip 40 are insulated from each other by a single transformer chip, the dielectric breakdown voltage of the signal transmission device 10 may be improved.

In addition, since the first transformer chip 50A and the second transformer chip 50B are provided separately from the first chip 30 and the second chip 40, a common transformer chip may be used for the different first chips 30 and second chips 40. This makes it possible to reduce manufacturing costs required to manufacture multiple types of signal transmission devices 10 in which at least one of the first chip 30 and the second chip 40 is different from each other.

The transformer chip 50 may be applied to devices other than the signal transmission device 10 of each embodiment.

In a first example, the transformer chip 50 may be applied to, for example, a primary-side circuit module. The primary-side circuit module includes a first chip 30, a transformer chip 50, and a sealing resin that seals these chips 30 and 50. The primary-side circuit module also includes a first die pad 61 on which both the first chip 30 and the transformer chip 50 are arranged. In this case, the primary-side circuit module corresponds to an “insulation module.” As shown in FIG. 22, the transformer chip 50 may include the primary-side circuit 13. In this case, the first chip 30 is omitted. Further, the primary-side circuit module may include a capacitor chip 130 instead of the transformer chip 50.

In a second example, the transformer chip 50 may be applied to, for example, a secondary-side circuit module. The secondary-side circuit module includes a second chip 40, a transformer chip 50, and a sealing resin that seals these chips 40 and 50. The secondary-side circuit module also includes a second die pad 71 on which the second chip 40 and the transformer chip 50 are arranged. In this case, the secondary-side circuit module corresponds to an “insulation module.” As shown in FIG. 23, the transformer chip 50 may include the secondary-side circuit 14. In this case, the second chip 40 is omitted. Further, the secondary-side circuit module may include a capacitor chip 130 instead of the transformer chip 50.

In a third example, the transformer chip 50 may be modularized. That is, the insulation module includes a transformer chip 50 and a sealing resin that seals the transformer chip 50. The insulation module also includes a die pad on which the transformer chip 50 is arranged. Further, the insulation module may include a capacitor chip 130 instead of the transformer chip 50.

Based on the above-described first to third examples, the configuration of the signal transmission device 10 may be changed as follows.

In one example, the signal transmission device 10 may include the above-mentioned primary-side circuit module and the second chip 40. In this case, the second chip 40 may be arranged on the second die pad 71, and both the second die pad 71 and the second chip 40 may be configured as a module sealed with a sealing resin. In other words, this module is provided separately from the primary-side circuit module. The signal transmission device 10 includes the primary-side circuit module and the above-mentioned module.

Additionally, in one example, the signal transmission device 10 may include the above-mentioned secondary-side circuit module and the first chip 30. In this case, the first chip 30 may be arranged on the first die pad 61, and both the first die pad 61 and the first chip 30 may be configured as a module sealed with a sealing resin. In other words, this module is provided separately from the secondary-side circuit module. The signal transmission device 10 includes the secondary-side circuit module and the above-mentioned module.

Additionally, in one example, the signal transmission device 10 may include an insulation module, a first chip 30, and a second chip 40. In this case, the first chip 30 may be arranged on the first die pad 61, and both the first die pad 61 and the first chip 30 may be configured as a first module sealed with a sealing resin. The second chip 40 may be arranged on the second die pad 71, and both the second die pad 71 and the second chip 40 may be configured as a second module sealed with a sealing resin. In other words, the first module, the second module, and the insulation module are provided separately from each other. The signal transmission device 10 includes the first module, the second module, and the insulation module.

In each of the above-described embodiments, the signal transmission device 10 transmits the set signal and the reset signal from the primary-side circuit 13 to the secondary-side circuit 14, but the present disclosure is not limited thereto. In one example, the signal transmission device 10 may transmit signals from the secondary-side circuit 14 to the primary-side circuit 13. In one example, the signal transmission device 10 may transmit signals bi-directionally such as transmitting a signal from the primary-side circuit 13 to the secondary-side circuit 14 and transmitting a signal from the secondary-side circuit 14 to the primary-side circuit 13.

One or more of the various examples described in the present disclosure may be combined to the extent that they are not technically contradictory. The terms such as “first,” “second,” and “third” in the present disclosure are used merely to distinguish between objects and are not intended to rank the objects.

In the present disclosure, “at least one selected from the group consisting of A and B” should be understood to mean “A alone, or B alone, or both A and B.” The term “on” as used in the present disclosure includes the meanings of “on” and “above” unless clearly stated otherwise in the context. Therefore, the expression “a first element is arranged on a second element” is intended that in some embodiments, the first element may be directly arranged on the second element in contact with the second element, while in other embodiments, the first element may be arranged above the second element without contacting the second element. That is, the term “on” does not exclude a structure in which other elements are formed between the first element and the second element.

The Z direction used in the present disclosure does not necessarily have to be the vertical direction, and it does not have to be exactly the same as the vertical direction. Therefore, various structures according to the present disclosure are not limited to the Z direction “up” and “down” described herein being the vertical direction “up” and “down.” For example, the X direction may be the vertical direction, or the Y direction may be the vertical direction.

### Supplementary Notes

The technical ideas that may be grasped from the present disclosure are described below. In addition, for the purpose of aiding understanding and not for the purpose of limitation, constituent elements described in supplementary notes are labeled with the reference numerals of the corresponding constituent elements in the above-described embodiments. The reference numerals are provided as examples to aid understanding, and the constituent elements described in supplementary notes should not be limited to the constituent elements indicated by the reference numerals.

### Supplementary Note 1

An insulation chip 50 includes:
a first unit 90; and
a second unit 100 bonded to the first unit 90 and smaller in size than the first unit 90 in a plan view;
wherein the first unit 90 includes:
a first element insulating layer 92 including a first element front surface 92A facing the second unit 100 and a first element back surface 92B opposite to the first element front surface 92A;
a first insulating element 21 buried in the first element insulating layer 92 at a position spaced apart from the first element front surface 92A in a thickness direction (Z direction) of the first element insulating layer 92; and
a first electrode pad 54 provided on the first element insulating layer 92 so as to be electrically connected to the first insulating element 21 and exposed from the first element front surface 92A,
wherein the second unit 100 includes:
a second element insulating layer 102 including a second element front surface 102A and a second element back surface 102B opposite to the second element front surface 102A; and
a second insulating element 22 buried in the second element insulating layer 102 at a position spaced apart from the second element front surface 102A in a thickness direction (Z direction) of the second element insulating layer 102, and
wherein in a unit bonding state in which the second unit 100 is bonded to the first unit 90, the first insulating element 21 and the second insulating element 22 are arranged to face each other in the thickness direction of the first element insulating layer 92, and the first electrode pad 54 is provided at a different position from the second unit 100 in a plan view.

### Supplementary Note 2

In the insulation chip of Supplementary Note 1 above, the first unit 90 includes a second electrode pad 55 electrically connected to the second insulating element 22 in the unit bonding state, and
in the unit bonding state, the second electrode pad 55 is provided at a position different from the second unit 100 in the first element insulating layer 92 in a plan view.

### Supplementary Note 3

In the insulation chip of Supplementary Note 2 above, the first unit 90 includes a first metal terminal 95 provided on the first element insulating layer 92 so as to be exposed from the first element front surface 92A,
the second unit 100 includes a second metal terminal 105 provided on the second element insulating layer 102 so as to be exposed from the second element front surface 102A, and
in the first unit 90 and the second unit 100, the first element front surface 92A and the second element front surface 102A are bonded to each other, and the first metal terminal 95 and the second metal terminal 105 are bonded to each other.

### Supplementary Note 4

In the insulation chip of Supplementary Note 3 above, both the first metal terminal 95 and the second metal terminal 105 are arranged at different positions from the first insulating element 21 and the second insulating element 22 in a plan view.

### Supplementary Note 5

In the insulation chip of Supplementary Note 3 or 4 above, both the first metal terminal 95 and the second metal terminal 105 are arranged outward from both the first insulating element 21 and the second insulating element 22 in a plan view.

### Supplementary Note 6

In the insulation chip of any one of Supplementary Notes 3 to 5 above, the first unit 90 includes a second electrode pad 55 electrically connected to the second insulating element 22 in the unit bonding state,
in a plan view, the first electrode pad 54 and the second electrode pad 55 are arranged in a distributed manner on both sides of the first insulating element 21 in a first direction (X direction) intersecting the first element insulating layer 92, and
in a plan view, the first metal terminal 95 is arranged between the second electrode pad 55 and the first insulating element 21 in the first direction (X direction).

### Supplementary Note 7

In the insulation chip of Supplementary Note 6 above, in a plan view, a distance DX3 between the first metal terminal 95 and the first insulating element 21 in the first direction (X direction) is larger than a distance DX4 between the first metal terminal 95 and the second electrode pad 55 in the first direction (X direction).

### Supplementary Note 8

In the insulation chip of any one of Supplementary Notes 3 to 7 above, the first metal terminal 95 is electrically connected to the second electrode pad 55, the second metal terminal 105 is electrically connected to the second insulating element 22, and
the second insulating element 22 and the second electrode pad 55 are electrically connected to each other by bonding the first metal terminal 95 and the second metal terminal 105.

### Supplementary Note 9

In the insulation chip of any one of Supplementary Notes 3 to 8 above, the first insulating element 21 is arranged to be closer to the first element back surface 92B than the first element front surface 92A in the thickness direction (Z direction) of the first element insulating layer 92.

### Supplementary Note 10

In the insulation chip of any one of Supplementary Notes 3 to 9 above, the second insulating element 22 is arranged to be closer to the second element back surface 102B than the second element front surface 102A in the thickness direction (Z direction) of the second element insulating layer 102.

### Supplementary Note 11

In the insulation chip of any one of Supplementary Notes 3 to 10 above, the first unit 90 includes:
a wiring layer 93A (94A) provided inside the first element insulating layer 92 and electrically connected to the first insulating element 21; and
a connection wiring 93B (94B) provided inside the first element insulating layer 92 and electrically connecting the wiring layer 93A (94A) and the first electrode pad 54.

### Supplementary Note 12

In the insulation chip of any one of Supplementary Notes 3 to 11 above, the second unit 100 includes:
a wiring layer 103A (104A) provided inside the second element insulating layer 102 and electrically connected to the second insulating element 22; and
a connection wiring 103B (104B) provided inside the second element insulating layer 102 and electrically connected to the wiring layer 103A (104A), wherein the second metal terminal 105 is electrically connected to the connection wiring 103B (104B) of the second unit 100, and in the unit bonding state, the second metal terminal 105 is electrically connected to the second electrode pad 55.

### Supplementary Note 13

In the insulation chip of Supplementary Note 1 above, the second unit 100 includes:
a second substrate 101 having a second substrate front surface 101A and a second substrate back surface 101B opposite to the second substrate front surface 101A, wherein the second substrate front surface 101A is in contact with the second element back surface 102B; and a second electrode pad 55 provided to be electrically connected to the second insulating element 22 and exposed from the second substrate back surface 101B.

### Supplementary Note 14

In the insulation chip of any one of Supplementary Notes 1 to 13 above, the first unit 90 and the second unit 100 are in the unit bonding state by bonding the first element front surface 92A and the second element front surface 102A in direct contact with each other.

### Supplementary Note 15

In the insulation chip of any one of Supplementary Notes 1 to 13 above, the first unit 90 and the second unit 100 are in the unit bonding state by bonding the first element front surface 92A and the second element front surface 102A to each other with an insulating bonding material AH.

### Supplementary Note 16

In the insulation chip of any one of Supplementary Notes 1 to 15 above, both the first insulating element 21 and the second insulating element 22 are formed by coils.

### Supplementary Note 17

In the insulation chip of any one of Supplementary Notes 1 to 15 above, both the first insulating element and the second insulating element are formed by electrode plates 121 (122).

### Supplementary Note 18

A signal transmission device including:
a first circuit 13;
a second circuit 14; and
the insulation chip 5 of any one of Supplementary Notes 1 to 17 above,
wherein the first circuit 13 and the second circuit 14 are configured to be connected to each other via the insulation chip 50 and transmit a signal via the insulation chip 50.

### Supplementary Note 19

In the signal transmission device of Supplementary Note 18 above, the first unit 90 includes the first circuit 13, and
the second circuit 14 is provided separately from the insulation chip 50.

### Supplementary Note 20

In the signal transmission device of Supplementary Note 18 above, the second unit 100 includes the second circuit 14, and
the first circuit 13 is provided separately from the insulation chip 50.

### Supplementary Note 21

In the signal transmission device of Supplementary Note 18 above, the first unit 90 includes the first circuit 13, and
the second unit 100 includes the second circuit 14.

### Supplementary Note 22

The signal transmission device of Supplementary Note 18 above further includes:
a first chip 30 including the first circuit 13; and
a second chip 40 including the second circuit 14.

### Supplementary Note 23

In the signal transmission device of Supplementary Note 22 above, the insulation chip 50 includes a first insulation chip 50A and a second insulation chip 50B, and
the second insulating element 22 of the first insulation chip 50A is electrically connected to the first insulating element 21 of the second insulation chip 50B.

### Supplementary Note 24

The signal transmission device of Supplementary Note 23 above further includes:
a first die pad 61 on which both the first chip 30 and the first insulation chip 50A are arranged; and
a second die pad 71 on which both the second chip 40 and the second insulation chip 50B are arranged.

### Supplementary Note 25

A method of manufacturing an insulation chip includes:
preparing a first semiconductor wafer 800 on which a plurality of first units 90 are formed;
preparing a second semiconductor wafer 900 on which a plurality of second units 100 smaller than the first units 90 in a plan view are formed;
segmenting the second units 100 from the second semiconductor wafer 900;
bonding the segmented second units 100 to a region of the first semiconductor wafer 800 where the first units 90 are formed; and
segmenting the first units 90 from the first semiconductor wafer 800,
wherein each of the first units 90 includes:
a first element insulating layer 92 including a first element front surface 92A facing the second unit 100 and a first element back surface 92B opposite to the first element front surface 92A;
a first insulating element 21 buried in the first element insulating layer 92 at a position spaced apart from the first element front surface 92A in a thickness direction (Z direction) of the first element insulating layer 92; and
a first electrode pad 54 provided on the first element insulating layer 92 so as to be electrically connected to the first insulating element 21 and exposed from the first element front surface 92A,
wherein each of the second unit 100 includes:
a second element insulating layer 102 including a second element front surface 102A and a second element back surface 102B opposite to the second element front surface 102A; and
a second insulating element 22 buried in the second element insulating layer 102 at a position spaced apart from the second element front surface 102A in a thickness direction (Z direction) of the second element insulating layer 102, and
wherein in the act of bonding the segmented second units 100 to the region of the first semiconductor wafer 800 where the first units 90 are formed, the second units 100 are arranged so that the first insulating element 21 and the second insulating element 22 are arranged to face each other in the thickness direction (Z direction) of the first element insulating layer 92 and the first electrode pad 54 is provided at a different position from the second units 100 in a plan view.

### Supplementary Note 26

In the method of Supplementary Note 25 above, in the act of bonding the segmented second units 100 to the region of the first semiconductor wafer 800 where the first units 90 are formed, in each of the first units 90 and each of the second units 100, the first element front surface 92A and the second element front surface 102A are bonded to each other in contact with each other.

### Supplementary Note 27

In the method of Supplementary Note 25 or 26 above, each of the first units 90 includes a first metal terminal 95 that is provided on the first element insulating layer 92 so as to be exposed from the first element front surface 92A, and is formed of a material containing Cu, and
each of the second units 100 includes a second metal terminal 105 that is provided on the second element insulating layer 102 so as to be exposed from the second element front surface 102A, and is formed of a material containing Cu, and
wherein in the act of bonding the segmented second units 100 to the region of the first semiconductor wafer 800 where the first units 90 are formed, the first metal terminal 95 and the second metal terminals 105 are in contact with each other and are bonded to each other.

The above description is merely an example. Those skilled in the art will appreciate that more possible combinations and substitutions are possible beyond the constituent elements and methods (manufacturing processes) listed for the purposes of illustrating the techniques of the present disclosure. The present disclosure is intended to cover all alternatives, modifications, and changes that fall within the scope of the present disclosure, including the claims.

What is claimed is:

1. An insulation chip comprising:
a first unit; and
a second unit bonded to the first unit and smaller in size than the first unit in a plan view;
wherein the first unit includes:
a first element insulating layer having a first element front surface facing the second unit and a first element back surface opposite to the first element front surface;
a first insulating element buried in the first element insulating layer at a position spaced apart from the first element front surface in a thickness direction of the first element insulating layer; and
a first electrode pad provided on the first element insulating layer so as to be electrically connected to the first insulating element and exposed from the first element front surface,
wherein the second unit includes:
a second element insulating layer having a second element front surface and a second element back surface opposite to the second element front surface; and
a second insulating element buried in the second element insulating layer at a position spaced apart from the second element front surface in a thickness direction of the second element insulating layer, and
wherein in a unit bonding state in which the second unit is bonded to the first unit, the first insulating element and the second insulating element are arranged to face each other in the thickness direction of the first element insulating layer, and the first electrode pad is provided at a different position from the second unit in a plan view.

2. The insulation chip of claim 1, wherein the first unit includes a second electrode pad electrically connected to the second insulating element in the unit bonding state, and
wherein in the unit bonding state, the second electrode pad is provided at a position different from the second unit in the first element insulating layer in a plan view.

3. The insulation chip of claim 2, wherein the first unit includes a first metal terminal provided on the first element insulating layer so as to be exposed from the first element front surface,
wherein the second unit includes a second metal terminal provided on the second element insulating layer so as to be exposed from the second element front surface, and
wherein in the first unit and the second unit, the first element front surface and the second element front surface are bonded to each other, and the first metal terminal and the second metal terminal are bonded to each other.

4. The insulation chip of claim 3, wherein both the first metal terminal and the second metal terminal are arranged at different positions from the first insulating element and the second insulating element in a plan view.

5. The insulation chip of claim 3, wherein both the first metal terminal and the second metal terminal are arranged outward from both the first insulating element and the second insulating element in a plan view.

6. The insulation chip of claim 3, wherein the first unit includes a second electrode pad electrically connected to the second insulating element in the unit bonding state,
wherein in a plan view, the first electrode pad and the second electrode pad are arranged in a distributed manner on both sides of the first insulating element in a first direction intersecting the first element insulating layer, and
wherein in a plan view, the first metal terminal is arranged between the second electrode pad and the first insulating element in the first direction.

7. The insulation chip of claim 6, wherein in a plan view, a distance between the first metal terminal and the first insulating element in the first direction is larger than a distance between the first metal terminal and the second electrode pad in the first direction.

8. The insulation chip of claim 3, wherein the first metal terminal is electrically connected to the second electrode pad,
wherein the second metal terminal is electrically connected to the second insulating element, and
wherein the second insulating element and the second electrode pad are electrically connected to each other by bonding the first metal terminal and the second metal terminal.

9. The insulation chip of claim 3, wherein the first insulating element is arranged to be closer to the first element back surface than the first element front surface in the thickness direction of the first element insulating layer.

10. The insulation chip of claim 3, wherein the second insulating element is arranged to be closer to the second element back surface than the second element front surface in the thickness direction of the second element insulating layer.

11. The insulation chip of claim 3, wherein the first unit includes:
a wiring layer provided inside the first element insulating layer and electrically connected to the first insulating element; and
a connection wiring provided inside the first element insulating layer and electrically connecting the wiring layer and the first electrode pad.

12. The insulation chip of claim 3, wherein the second unit includes:
a wiring layer provided inside the second element insulating layer and electrically connected to the second insulating element; and
a connection wiring provided inside the second element insulating layer and electrically connected to the wiring layer,
wherein the second metal terminal is electrically connected to the connection wiring of the second unit, and
wherein in the unit bonding state, the second metal terminal is electrically connected to the second electrode pad.

13. The insulation chip of claim 1, wherein the second unit includes:
a second substrate having a second substrate front surface and a second substrate back surface opposite to the second substrate front surface, wherein the second substrate front surface is in contact with the second element back surface; and
a second electrode pad provided to be electrically connected to the second insulating element and exposed from the second substrate back surface.

14. The insulation chip of claim 1, wherein the first unit and the second unit are in the unit bonding state by bonding the first element front surface and the second element front surface in direct contact with each other.

15. The insulation chip of claim 1, wherein the first unit and the second unit are in the unit bonding state by bonding the first element front surface and the second element front surface to each other with an insulating bonding material.

16. The insulation chip of claim 1, wherein both the first insulating element and the second insulating element are formed by coils.

17. The insulation chip of claim 1, wherein both the first insulating element and the second insulating element are formed by electrode plates.

18. A signal transmission device comprising:
a first circuit;
a second circuit; and
an insulation chip of claim 1,
wherein the first circuit and the second circuit are configured to be connected to each other via the insulation chip and transmit a signal via the insulation chip.

19. The signal transmission device of claim 18, wherein the first unit includes the first circuit, and
wherein the second circuit is provided separately from the insulation chip.

20. The signal transmission device of claim 18, wherein the second unit includes the second circuit, and
wherein the first circuit is provided separately from the insulation chip.
